(19) United States
(12) Patent Application Publication
(10) Pub. No.: US 2025/0275352 A1
(43) Pub. Date: Aug. 28, 2025

(54) ORGANIC LIGHT-EMITTING DISPLAY DEVICE

(71) Applicant: LG Display Co., Ltd., Seoul (KR)

(72) Inventors: Sohee LEE, Paju-si (KR); Moonsung KIL, Paju-si (KR)

(21) Appl. No.: 18/910,968

(22) Filed: Oct. 9, 2024

(30) Foreign Application Priority Data
Feb. 27, 2024 (KR) 10-2024-0027959

(51) Int. Cl. H10K 50/15; H10K 59/35; H10K 101/40

(52) U.S. Cl. CPC H10K 50/156; H10K 59/353; H10K 2101/40

(57) ABSTRACT

Provided is an organic light-emitting display device. The organic light-emitting display device includes a substrate on which red, green, and blue subpixels are disposed, the substrate containing a first display area including a light-emitting area and a transmissive area, and a second display area configured to surround the first display area; anodes separated and respectively disposed in the red, green, and blue subpixels; hole transport layers disposed on the anodes; red, green, and blue organic light-emitting layers respectively disposed in the red, green, and blue subpixels on the hole transport layer; a second auxiliary hole transport layer disposed between the green organic light-emitting layer and the hole transport layer of the green subpixel; a third auxiliary hole transport layer disposed on the second auxiliary hole transport layer of the green subpixel and having lower hole mobility than the second auxiliary hole transport layer; electron transport layers disposed on the red, green, and blue organic light-emitting layers; and a cathode disposed on the electron transport layer. A top surface of the anode of the green subpixel is positioned to be lower than a top surface of the anode of the red subpixel and a top surface of the anode of the blue subpixel.

### CROSS-REFERENCE TO RELATED APPLICATIONS

This application claims the priority of Korean Patent Application No. 10-2024-0027959 filed on Feb. 27, 2024, in the Korean Intellectual Property Office, the entire disclosure of which is incorporated herein by reference.

### BACKGROUND

### Technical Field

The present disclosure relates to organic light-emitting display devices, and more particularly, to organic light-emitting display devices capable of suppressing a drive delay of a subpixel and a leakage current and improving sensing sensitivity and reliability of an electronic optical device disposed in a transmissive area.

### Description of the Related Art

Display devices, which visually display electrical information signals, are being rapidly developed. Various studies are being continuously conducted to develop a variety of display devices which are thin and lightweight, consume low power, and have improved performance.

As the representative display devices, there may be a liquid crystal display device (LCD), a field emission display device (FED), an electrowetting display device (EWD), an organic light-emitting display device (OLED), and the like.

An electroluminescent display device, as the representative organic light-emitting display device, refers to a display device that autonomously emits light. Unlike a liquid crystal display devices, electroluminescent display devices do not require a separate light source and thus may be manufactured as a lightweight, thin display devices. In addition, electroluminescent display devices are advantageous in terms of power consumption because electroluminescent display devices operate at low voltages. Further, electroluminescent display devices are expected to be adopted in various fields because electroluminescent display devices are also excellent in the provision of colors, with fast response speeds, viewing angles, and contrast ratios (CRs).

Recently, multimedia functions of mobile terminals have been improved. For example, a display device basically equipped with an electronic optical device, such as a camera or sensor, embedded in a front surface of the display device has been developed. However, the camera or sensor disposed on the front surface of the display device may restrict a screen design. The display device adopts a design including a notch or punch hole to reduce a space occupied by the camera or sensor disposed on the front surface of the display device. However, a screen size is still restricted, which makes it difficult to implement a full-screen display.

To implement the full-screen display, there has been proposed a configuration in which an area, in which low-resolution pixels are disposed, is provided in a screen of a display device, and a camera and/or various types of sensors are disposed in the area in which the low-resolution pixels are disposed.

### BRIEF SUMMARY

An object of the present disclosure is to provide organic light-emitting display devices capable of protecting an electronic optical device, such as a camera or sensor, disposed in a transmissive area in a display area from being affected by light inadvertently emitted from a light-emitting element.

Another object to be achieved by the present disclosure is to provide organic light-emitting display devices capable of suppressing a drive delay of a subpixel and a leakage current, and improving sensing sensitivity and reliability of electronic optical devices disposed in a transmissive area.

Objects of the present disclosure are not limited to the above-mentioned objects, and other objects, which are not mentioned above, can be clearly understood by those skilled in the art from the following descriptions.

An organic light-emitting display device according to an embodiment of the present specification includes: a substrate on which red, green, and blue subpixels are disposed, the substrate including a first display area including a light-emitting area and a transmissive area, and a second display area configured to surround the first display area; anodes separated and respectively disposed in the red, green, and blue subpixels; hole transport layers disposed on the anodes; red, green, and blue organic light-emitting layers respectively disposed in the red, green, and blue subpixels on the hole transport layer; a second auxiliary hole transport layer disposed between the green organic light-emitting layer and the hole transport layer of the green subpixel; a third auxiliary hole transport layer disposed on the second auxiliary hole transport layer of the green subpixel and having lower hole mobility than the second auxiliary hole transport layer; electron transport layers disposed on the red, green, and blue organic light-emitting layers; and a cathode disposed on the electron transport layer, in which a top surface of the anode of the green subpixel is positioned to be lower than a top surface of the anode of the red subpixel and a top surface of the anode of the blue subpixel.

Other detailed matters of the exemplary embodiments are included in the detailed description and the drawings.

According to the organic light-emitting display device according to the embodiment of the present specification, the camera or sensor is disposed at the lower end of the light-emitting element or the touch electrode in the display area, such that the display or touch at the upper side thereof may not be disconnected.

Organic light-emitting display devices according to embodiments of the present disclosure may suppress a drive delay of the green subpixel and a leakage current, and improve the sensing sensitivity and reliability of the electronic optical device disposed in the transmissive area.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIGS. 1A to 1D are schematic top plan views of a display device according to an embodiment of the present specification;

FIG. 2 is a system configuration view of the display device according to the embodiment of the present specification;

FIG. 3 is an equivalent circuit diagram of a subpixel of a display panel according to the embodiment of the present specification;

FIG. 4 is a view illustrating an example in which the subpixels are disposed in a display area according to the embodiment of the present specification;

FIG. 5A is a view illustrating an example in which signal lines are disposed in a first optical area and a normal area according to the embodiment of the present specification;

FIG. 5B is a view illustrating an example in which the signal lines are disposed in a second optical area and the normal area according to the embodiment of the present specification;

FIG. 6 is a view illustrating a cross-sectional structure of one pixel disposed in the normal area according to the embodiment of the present specification;

FIG. 7 is a view illustrating a cross-sectional structure of a light-emitting area and a transmissive area of an optical area according to the embodiment of the present specification;

FIG. 8 is a schematic view of one pixel of an organic light-emitting display device according to the embodiment of the present specification;

FIG. 9 is a schematic view of one pixel of an organic light-emitting display device according to another embodiment of the present specification;

FIGS. 10A to 10C are graphs illustrating electrical properties of red, green, and blue subpixels according to Comparative Embodiment 1;

FIGS. 11A to 11C are graphs illustrating electrical properties of green subpixels according to Comparative Embodiment 1 and Embodiments 1 and 2; and

FIGS. 12A to 12C band diagrams illustrating HOMO-LUMO energy levels of light-emitting layers that constitute light-emitting elements of red subpixels, green subpixels, and blue subpixels according to Embodiments 1 and 2.

### DETAILED DESCRIPTION

Advantages and characteristics of the present disclosure and methods of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only.” Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

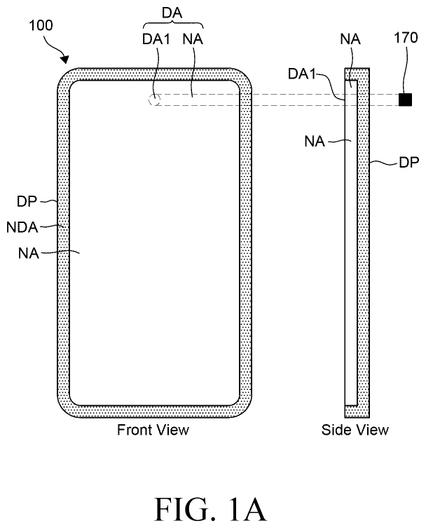

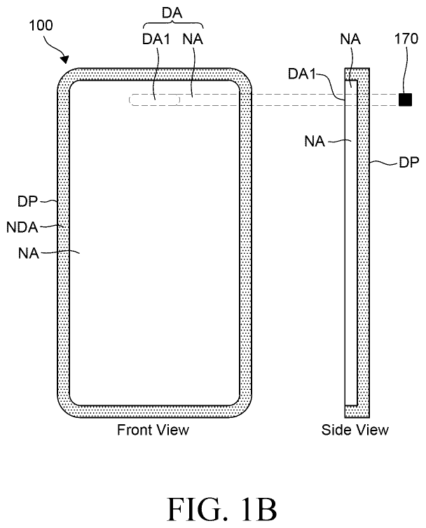

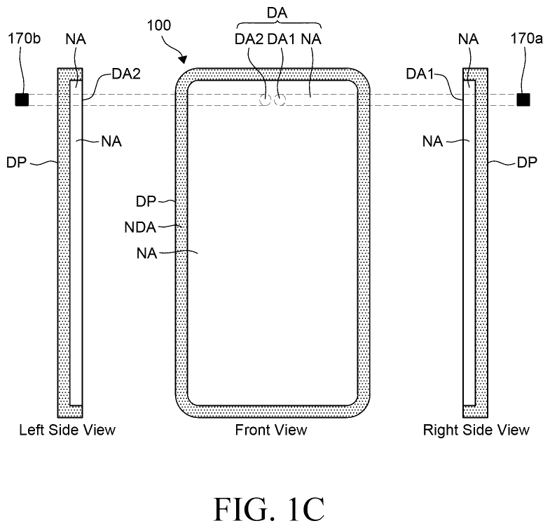

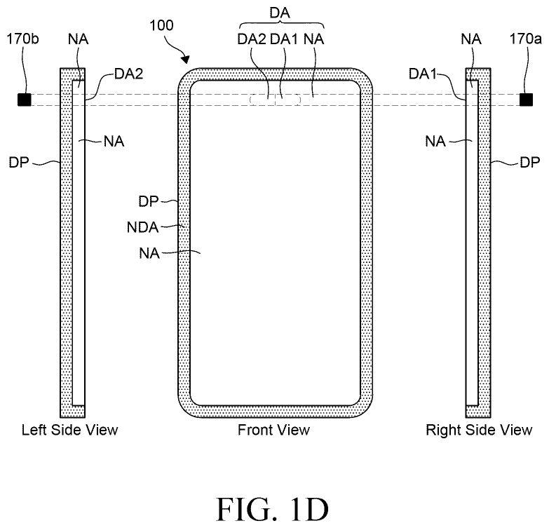

FIGS. 1A to 1D are schematic top plan views of a display device according to an embodiment of the present specification.

With reference to FIGS. 1A to 1D, an organic light-emitting display device 100 according to an embodiment of the present specification may include a display panel DP configured to display images, and one or more electronic optical devices 170, 170a, and 170b. The electronic optical devices 170, 170a, and 170b may each include a light-receiving device, such as a camera or sensor, that receives light.

The display panel DP is a panel configured to display images to a user.

The display panel DP may include a display element configured to display images, a driving element configured to operate the display element, and lines configured to transmit various types of signals to the display element and the driving element. Different display elements may be defined depending on the types of display panels DP. For example, in a case in which the display panel DP is an organic light-emitting display panel, the display element may be an organic light-emitting element including an anode, a light-emitting layer, and a cathode. In addition, the organic light-emitting display device 100 according to the embodiment of the present specification may be a flexible organic light-emitting display device.

Meanwhile, the display panel DP may include a substrate, and a plurality of insulation films, transistor layers, and light-emitting element layers disposed on the substrate. To display images, the display panel DP may include a plurality of subpixels, and various types of signal lines configured to operate the plurality of subpixels. The signal lines may include a plurality of data lines, a plurality of gate lines, a plurality of power lines, and the like. In this case, the plurality of subpixels may each include a transistor positioned on a transistor layer, and a light-emitting element positioned on a light-emitting element layer.

The display panel DP may include the display area DA in which images are displayed, and the non-display area NDA in which no image is displayed.

The display area DA may include the plurality of subpixels constituting a plurality of pixels, and a circuit configured to operate the plurality of subpixels. The plurality of subpixels is minimum units constituting the display area DA. The display element may be disposed in each of the plurality of subpixels. The plurality of subpixels may constitute the pixel. For example, the plurality of subpixels may each include an organic light-emitting element including an anode, a light-emitting layer, and a cathode. However, the present specification is not limited thereto. In addition, the circuit configured to operate the plurality of subpixels may include driving elements, lines, and the like. For example, the circuit may include a thin-film transistor, a storage capacitor, a gate line, a data line, and the like. However, the present specification is not limited thereto.

The non-display area NDA may be bent, such that the non-display area NDA is not visible from a front surface. The non-display area NDA may be covered by a casing (not illustrated). The non-display area NDA is called a bezel area.

Various lines and circuits for operating the organic light-emitting element in the display area DA may be disposed in the non-display area NDA. For example, the non-display area NDA may include link lines for transmitting signals to the plurality of subpixels and the circuit in the display area DA. The non-display area NDA may include gate-in-panel (GIP) lines or drive ICs such as gate driver ICs and data driver ICs. However, the present specification is not limited thereto.

FIGS. 1A to 1D illustrate that the non-display area NDA surrounds the display area DA having a quadrangular shape. However, the shapes and arrangements of the display area DA and the non-display area NDA are not limited to the example illustrated in FIGS. 1A to 1D. That is, the display area DA and the non-display area NDA may be suitable for the design of an electronic device equipped with the organic light-emitting display device 100. For example, an exemplary shape of the display area DA may also be a pentagonal shape, a hexagonal shape, a circular shape, an elliptical shape, or the like.

The organic light-emitting display device 100 may further include various additional elements configured to generate various signals or operate a pixel in the display area DA. The additional elements for operating the pixel may include an inverter circuit, a multiplexer, an electrostatic discharge (ESD) circuit, and the like. The organic light-emitting display device 100 may also include additional elements related to functions other than the function of operating the pixel. For example, the organic light-emitting display device 100 may further include additional elements that provide a touch detection function, a user certification function (e.g., fingerprint recognition), a multi-level pressure detection function, a tactile feedback function, and the like. The above-mentioned additional elements may be positioned in the non-display area NDA and/or an external circuit connected to a connection interface.

With reference to FIGS. 1A to 1D, in the organic light-emitting display device 100 according to the embodiments of the present specification, the one or more electronic optical devices 170, 170a, and 170b are electronic components positioned at a lower side (a side opposite to a visual surface) of the display panel DP.

The light may enter the front surface (visual surface) of the display panel DP, passes through the display panel DP, and then propagate to the one or more electronic optical devices 170, 170a, and 170b positioned at the lower side (the side opposite to the visual surface) of the display panel DP.

The one or more electronic optical devices 170, 170a, and 170b may be devices that receive the light having passed through the display panel DP and perform predetermined functions in response to the received light.

For example, the electronic optical devices 170, 170a, and 170b may include any one or more of an image capturing device, such as a camera (image sensor), and a detection sensor, such as a proximity sensor and an illuminance sensor.

With reference to FIGS. 1A to 1D, in the organic light-emitting display device 100 according to the embodiments of the present specification, the display area DA may include a normal area NA and one or more optical areas DA1 and DA2.

The one or more optical areas DA1 and DA2 may be areas that overlap with the one or more electronic optical devices 170, 170a, and 170b.

According to the example in FIG. 1A, the display area DA may include the normal area NA and a first optical area DA1. In this case, at least a part of the first optical area DA1 may overlap with a first electronic optical device 170.

FIG. 1A illustrates that the first optical area DA1 has a circular structure. However, the shape of the first optical area DA1 according to the embodiment of the present specification is not limited thereto. For example, as illustrated in FIG. 1B, the shape of the first optical area DA1 may be an octagonal shape or various polygonal shapes.

According to the example in FIG. 1C, the display area DA may include the normal area NA, the first optical area DA1, and a second optical area DA2. In the example in FIG. 1C, the normal area NA may be present between the first optical area DA1 and the second optical area DA2. In this case, at least a part of the first optical area DA1 may overlap with the first electronic optical device 170a, and at least a part of the second optical area DA2 may overlap with the second electronic optical device 170b.

According to the example in FIG. 1D, the display area DA may include the normal area NA, the first optical area DA1, and the second optical area DA2. In the example in FIG. 1D, the normal area NA is not present between the first optical area DA1 and the second optical area DA2. That is, the first optical area DA1 and the second optical area DA2 may adjoin each other. In this case, at least a part of the first optical area DA1 may overlap with the first electronic optical device 170a, and at least a part of the second optical area DA2 may overlap with the second electronic optical device 170b.

The one or more optical areas DA1 and DA2 each need to have both an image display structure and a light transmission structure. That is, because the one or more optical areas DA1 and DA2 are partial areas of the display area DA, the subpixels for displaying images need to be disposed in the one or more optical areas DA1 and DA2. The one or more optical areas DA1 and DA2 each need to have the light transmission structure for transmitting light to the one or more electronic optical devices 170, 170a, and 170b.

The one or more electronic optical devices 170, 170a, and 170b are devices that need to receive light. However, the one or more electronic optical devices 170, 170a, and 170b are positioned at a rear side (the lower side, i.e., the side opposite to the visual surface) of the display panel DP and receive the light having passed through the display panel DP.

The one or more electronic optical devices 170, 170a, and 170b are not exposed to the front surface (visual surface) of the display panel DP. Therefore, the user does not visually recognize the electronic optical devices 170, 170a, and 170b when the user looks at the front surface of the organic light-emitting display device 100.

For example, the first electronic optical device 170 (170a) may be a camera, and the second electronic optical device 170b may be a detection sensor such as a proximity sensor or an illuminance sensor. For example, the detection sensor may be an infrared sensor that detects infrared rays.

On the contrary, the first electronic optical device 170 (170a) may be a detection sensor, and the second electronic optical device 170b may be a camera.

Hereinafter, for convenience of description, an example will be described in which the first electronic optical device 170 (170a) is a camera, and the second electronic optical device 170b is a detection sensor. In this case, the camera may be a camera lens or an image sensor.

In case that the first electronic optical device 170 (170a) is a camera, the camera may be positioned at the rear side (lower side) of the display panel DP. However, the camera may be the front surface camera configured to capture an image of an object disposed forward of the display panel DP. Therefore, the user may capture an image by using the camera, which is not visible from the visual surface, while looking at the visual surface of the display panel DP.

The normal area NA and the one or more optical areas DA1 and DA2, which are included in the display area DA, are areas in which images may be displayed. However, the normal area NA is an area that does not require the light transmission structure, and the one or more optical areas DA1 and DA2 are areas that need to have the light transmission structures.

Therefore, the one or more optical areas DA1 and DA2 each need to have transmittance at a predetermined level or higher. The normal area NA may not have optical transmittance or have low transmittance at less than the predetermined level.

For example, the one or more optical areas DA1 and DA2 and the normal area NA may be different in resolution, subpixel arrangement structure, number of subpixels per unit area, electrode structure, line structure, electrode arrangement structure, line arrangement structure, or the like.

For example, the number of subpixels per unit area in each of the one or more optical areas DA1 and DA2 may be smaller than the number of subpixels per unit area in the normal area NA. That is, the resolution in each of the one or more optical areas DA1 and DA2 may be lower than the resolution in the normal area NA. In this case, the number of subpixels per unit area may be a criterion for measuring the resolution and may also be referred to as PPI (pixels per inch) that means the number of pixels within 1 inch.

For example, the number of subpixels per unit area in the first optical area DA1 may be smaller than the number of subpixels per unit area in the normal area NA. In addition, the number of subpixels per unit area in the second optical area DA2 may be equal to or larger than the number of subpixels per unit area in the first optical area DA1.

The first optical area DA1 may have various shapes such as a circular shape, an elliptical shape, a quadrangular shape, a hexagonal shape, or an octagonal shape. The second optical area DA2 may have various shapes such as a circular shape, an elliptical shape, a quadrangular shape, a hexagonal shape, or an octagonal shape. The first optical area DA1 and the second optical area DA2 may have the same shape or different shapes.

With reference to FIG. 1C, in case that the first optical area DA1 and the second optical area DA2 adjoin each other, an overall optical area including the first optical area DA1 and the second optical area DA2 may have various shapes such as a circular shape, an elliptical shape, a quadrangular shape, a hexagonal shape, or an octagonal shape.

Hereinafter, for convenience of description, an example will be described in which the first optical area DA1 and the second optical area DA2 each have a circular shape.

In the organic light-emitting display device 100 according to the embodiment of the present specification, in case that the first electronic optical device 170 (170a), which is hidden at the lower side of the display panel DP without being exposed to the outside, is a camera, the organic light-emitting display device 100 according to the embodiment of the present specification may be a display to which an under-display camera (UDC) technology is applied.

According to this configuration, in the organic light-emitting display device 100 according to the embodiment of the present specification, a notch or camera hole for exposing a camera need not be formed in the display panel DP, such that an area of the display area DA does not decrease. Therefore, because the notch or camera hole for exposing the camera need not be formed in the display panel DP, a size of a bezel area may decrease, and a design constraint may be eliminated, such that a degree of freedom may increase.

In the organic light-emitting display device 100 according to the embodiment of the present specification, even though the one or more electronic optical devices 170, 170a, and 170b are positioned to be hidden at the rear side of the display panel DP, the one or more electronic optical devices 170, 170a, and 170b need to normally receive light and normally perform the predetermined functions.

In addition, in the organic light-emitting display device 100 according to the embodiment of the present specification, even though the one or more electronic optical devices 170, 170a, and 170b are positioned to be hidden at the rear side of the display panel DP and positioned to overlap with the display area DA, images need to be normally displayed in the one or more optical areas DA1 and DA2 that overlap with the one or more electronic optical devices 170, 170a, and 170b in the display area DA.

Therefore, the organic light-emitting display device 100 according to the embodiment of the present specification may have a structure capable of improving the transmittance of the first optical area DA1 and the second optical area DA2 that overlap with the electronic optical devices 170, 170a, and 170b.

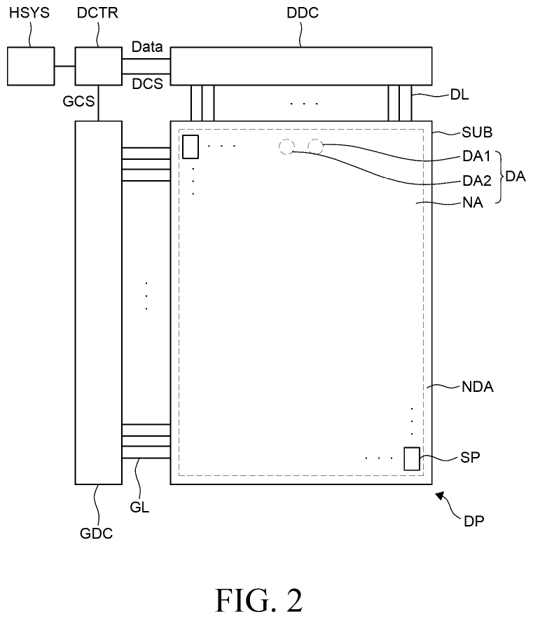

FIG. 2 is a system configuration view of the display device according to the embodiment of the present specification.

With reference to FIG. 2, the organic light-emitting display device 100 may include the display panel DP and a display drive circuit that are constituent elements for displaying images. The display drive circuit may be a circuit for operating the display panel DP and include a data drive circuit DDC, a gate drive circuit GDC, and a display controller DCTR.

The display panel DP may include the display area DA in which images are displayed, and the non-display area NDA in which no image is displayed. The non-display area NDA may be an outer peripheral area of the display area DA and also referred to as a bezel area. The entirety or a part of the non-display area NDA may be an area visible from the front surface of the organic light-emitting display device 100 or an area that is bent and not visible from the front surface of the organic light-emitting display device 100.

The display panel DP may include a substrate SUB, and a plurality of subpixels SP disposed on the substrate SUB. In addition, the display panel DP may further include various types of signal lines to operate the plurality of subpixels SP.

The organic light-emitting display device 100 according to the embodiments of the present specification may be an organic spontaneous light-emitting display device in which the display panel DP autonomously emits light. The plurality of subpixels SP may each include the light-emitting element.

For example, the organic light-emitting display device 100 according to the embodiments of the present specification may be an organic light-emitting display device in which a light-emitting element is implemented as an organic light-emitting diode (OLED). As another example, the organic light-emitting display device 100 according to the embodiments of the present specification may be an inorganic light-emitting display device in which a light-emitting element is implemented as a light-emitting diode made of an inorganic material. As still another example, the organic light-emitting display device 100 according to the embodiments of the present specification may be a quantum dot display device implemented by quantum dots, which are semiconductor crystals, so that a light-emitting element autonomously emits light.

The structure of each of the plurality of subpixels SP may vary depending on the type of organic light-emitting display device 100. For example, in case that the organic light-emitting display device 100 is a spontaneous light-emitting display device having the subpixel SP that autonomously emits light, the subpixels SP may each include a light-emitting element configured to autonomously emit light, one or more transistors, and one or more capacitors.

Various types of signal lines may include a plurality of data lines DL configured to transmit data signals (also referred to as data voltages or image signals), and a plurality of gate lines GL configured to transmit gate signals (also referred to as scan signals).

The plurality of data lines DL and the plurality of gate lines GL may intersect one another. The plurality of data lines DL may each be disposed while extending in a first direction. The plurality of gate lines GL may each be disposed while extending in a second direction. In this case, the first direction may be a column direction, and the second direction may be a row direction. Alternatively, the first direction may be a row direction, and the second direction may be a column direction.

The data drive circuit DDC may be a circuit for operating the plurality of data lines DL and output data signals to the plurality of data lines DL. The gate drive circuit GDC may be a circuit for operating the plurality of gate lines GL and output gate signals to the plurality of gate lines GL.

The display controller DCTR may be a device for controlling the data drive circuit DDC and the gate drive circuit GDC and control driving timing for the plurality of data lines DL and driving timing for the plurality of gate lines GL.

The display controller DCTR may supply a data drive control signal DCS to the data drive circuit DDC to control in order to control the data drive circuit DDC and supply a gate drive control signal GCS to the gate drive circuit GDC in order to control the gate drive circuit GDC.

The display controller DCTR may receive input image data from a host system HSYS and supply image data Data to the data drive circuit DDC on the basis of the input image data.

The data drive circuit DDC may supply the data signals to the plurality of data lines DL on the basis of driving timing control of the display controller DCTR. The data drive circuit DDC may receive digital image data Data from the display controller DCTR, convert the received image data Data into analog data signals, and output the analog data signals to the plurality of data lines DL.

The gate drive circuit GDC may supply the gate signals to the plurality of gate lines GL on the basis of timing control of the display controller DCTR. The gate drive circuit GDC may generate gate signals by receiving a first gate voltage, which corresponds to a turn-on level voltage, and a second gate voltage, which corresponds to a turn-off level voltage, together with various types of gate driving control signals GCS and supply the generated gate signals to the plurality of gate lines GL.

The gate drive circuit GDC supplies the gate signal to the gate line GL in response to the gate drive control signal GCS supplied from the display controller DCTR. The gate drive circuit GDC may be disposed at one side or two opposite sides of the display panel DP in a gate-in-panel (GIP) manner.

The gate drive circuit GDC sequentially outputs the gate signals to the plurality of gate lines GL under the control of the display controller DCTR. The gate drive circuit GDC may shift the gate signals by using a shift register and sequentially supply the signals to the gate lines GL.

In the organic light-emitting display device, the gate signals may include the scan signal SC and the light emission control signal EM. The scan signal SC includes a scan signal pulse that swings between the first gate voltage and the second gate voltage. The light-emitting control signal EM may include a light-emitting control signal pulse that swings between a third gate voltage and a fourth gate voltage.

The scan pulse is synchronized with a data voltage Vdata and selects the subpixels SP on the line to which data is written. The light-emitting control signal EM defines light-emitting time of each of the subpixels SP.

The gate drive circuit GDC may include a light-emitting control signal driver EDC configured to output the light-emitting control signal EM, and one or more scan drivers SDC configured to output the scan signal SC.

The light-emitting control signal driver EDC outputs the light-emitting control signal EM in response to a start pulse and a shift clock from the display controller DCTR and sequentially shifts the light-emitting control signal pulse in response to the shift clock.

The one or more scan drivers SDC output the scan signal SC in response to the start pulse and the shift clock from the display controller DCTR and shift the scan signal pulse in accordance with a shift clock timing.

In the gate drive circuit GDC disposed in the GIP manner, the shift registers may be configured symmetrically at two opposite sides of the display area DA. In addition, the gate drive circuit GDC may be configured such that the shift register at one side of the display area DA includes at least one scan driver SDC and a light-emitting control signal driver, and the shift register at the other side of the display area DA includes at least one scan driver SDC. However, the present specification is not limited thereto. The light-emitting control signal driver EDC and the at least one scan driver SDC may be differently disposed according to the embodiment.

The data drive circuit DDC may be connected to the display panel DP in a tape-automated bonding (TAB) manner, connected to a bonding pad of the display panel DP in a chip-on-glass (COG) or chip-on-panel (COP) manner, or connected to the display panel DP in a chip-on-film (COF) manner.

The gate drive circuit GDC may be connected to the display panel DP in a tape-automated bonding (TAB) manner, connected to the bonding pad of the display panel DP in a chip-on-glass (COG) or chip-on-panel (COP) manner, or connected to the display panel DP in a chip-on-film (COF) manner. Alternatively, the gate drive circuit GDC may be formed as a gate1-in-panel (GIP) type in the non-display area NDA of the display panel DP. The gate drive circuit GDC may be disposed on the substrate or connected to the substrate. That is, in case that the gate drive circuit GDC is the GIP type, the gate drive circuit GDC may be disposed in the non-display area NDA of the substrate. In case that the gate drive circuit GDC is a chip-on-glass (COG) type, a chip-on-film (COF) type, or the like, the gate drive circuit GDC may be connected to the substrate.

Meanwhile, at least one of the data drive circuit DDC and the gate drive circuit GDC may be disposed in the display area DA of the display panel DP. For example, at least one of the data drive circuit DDC and the gate drive circuit GDC may be disposed so as not to overlap with the subpixels SP or disposed to overlap with some or all of the subpixels SP.

The data drive circuit DDC may be connected to one side (e.g., upper or lower side) of the display panel DP. Depending on operating methods, panel designing methods, or the like, the data drive circuits DDC may be connected to both the two opposite sides (e.g., upper and lower sides) of the display panel DP or connected to two or more side surfaces among the four side surfaces of the display panel DP.

The gate drive circuit GDC may be connected to one side (e.g., left or right side) of the display panel DP. Depending on operating methods, panel designing methods, or the like, the gate drive circuits GDC may be connected to both the two opposite sides (e.g., left and right sides) of the display panel DP or connected to two or more side surfaces among the four side surfaces of the display panel DP.

The display controller DCTR may be implemented as a component provided separately from the data drive circuit DDC or implemented as an integrated circuit by being integrated with the data drive circuit DDC.

The display controller DCTR may be a timing controller used for a typical display technology or may be a control device including a timing controller and configured to further perform other control functions. Alternatively, the display controller DCTR may be a control device different from a timing controller or may be a circuit disposed in a control device. The display controller DCTR may be implemented as an electronic component or various circuits such as integrated circuits (ICs), field programmable GATE1 arrays (FPGAs), application specific integrated circuits (ASICs), or processors.

The display controller DCTR may be mounted on a printed circuit board, a flexible printed circuit, or the like and electrically connected to the data drive circuit DDC and the gate drive circuit GDC through the printed circuit board, the flexible printed circuit, or the like.

The display controller DCTR may transmit a signal to the data drive circuit DDC and receive a signal from the data drive circuit DDC in accordance with one or more predetermined interfaces. In this case, for example, the interfaces may include a low-voltage differential signaling (LVDS) interface, an embedded clock point-to-point interface (EPI), a serial peripheral interface (SPI), and the like.

To further provide a touch sensing function in addition to the image display function, the organic light-emitting display device 100 according to the embodiments of the present specification may include a touch sensor, and a touch sensing circuit configured to sense the touch sensor to detect whether a touch is made by a touch object such as a finger, a pen, or the like or to detect a touch position.

The touch sensing circuit may further include a touch drive circuit configured to operate the touch sensor, sense the touch sensor, and produce and output touch sensing data, and a touch controller configured to use the touch sensing data to detect the occurrence of a touch or a touch position.

The touch sensor may include a plurality of touch electrodes. The touch sensor may further include a plurality of touch lines configured to electrically connect the plurality of touch electrodes and the touch drive circuit.

The touch sensor may be provided in the form of a touch panel disposed outside the display panel DP or provided in the display panel DP. In case that the touch sensor is provided in the form of a touch panel present outside the display panel DP, the touch sensor is called an externally-carried touch sensor. In case that the touch sensor is an externally-carried touch sensor, the touch panel and the display panel DP may be separately manufactured and coupled to each other during an assembling process. The externally-carried touch panel may include a touch panel substrate, and the plurality of touch electrodes disposed on the touch panel substrate.

In case that the touch sensor is present inside the display panel DP, the touch sensor may be provided on the substrate SUB together with signal lines and electrodes related to a display operation during a process of manufacturing the display panel DP.

A touch drive circuit TDC may supply a touch driving signal to at least one of the plurality of touch electrodes, sense at least one of the plurality of touch electrodes, and produce touch sensing data.

The touch sensing circuit may perform touch sensing in a self-capacitance sensing manner or a mutual-capacitance sensing manner.

In case that the touch sensing circuit performs touch sensing in a self-capacitance sensing manner, the touch sensing circuit may perform the touch sensing on the basis of capacitance between each of the touch electrodes and the touch object (e.g., a finger, a pen, or the like).

According to the self-capacitance sensing manner, the plurality of touch electrodes may serve as a drive touch electrode and a sensing touch electrode. The touch drive circuit TDC may operate all or some of the plurality of touch electrodes and sense all or some of the plurality of touch electrodes.

In case that the touch sensing circuit performs touch sensing in a mutual-capacitance sensing manner, the touch sensing circuit may perform the touch sensing on the basis of capacitance between the touch electrodes.

According to the mutual-capacitance sensing manner, the plurality of touch electrodes is classified into drive touch electrodes and sensing touch electrodes. The touch drive circuit may operate the drive touch electrodes and sense the sensing touch electrodes.

The touch drive circuit and the touch controller, which are included in the touch sensing circuit, may be implemented as separate devices or a single device. In addition, the touch drive circuit and the data drive circuit DDC may be implemented as separate devices or a single device.

In addition, the organic light-emitting display device 100 may further include a power supply circuit configured to supply various types of power to the display drive circuit and/or the touch sensing circuit.

The organic light-emitting display device 100 according to the embodiments of the present specification may be a mobile terminal such as a smartphone or a tablet, or a monitor or a television (TV) having various sizes. However, the present specification is not limited thereto. The organic light-emitting display device 100 may be one of the displays having various types and various sizes and being capable of displaying information or images.

As described above, the display area DA of the display panel DP may include the normal area NA and the one or more optical areas DA1 and DA2.

The normal area NA and the one or more optical areas DA1 and DA2 are areas in which images may be displayed. However, the normal area NA is an area that does not require the light transmission structure, and the one or more optical areas DA1 and DA2 are areas that need to have the light transmission structures.

As described above, the display area DA of the display panel DP may include the normal area NA and the one or more optical areas DA1 and DA2.

Hereinafter, for convenience of description, it is assumed that the display area DA includes both the first optical area DA1 and the second optical area DA2 (FIGS. 1C and 1D).

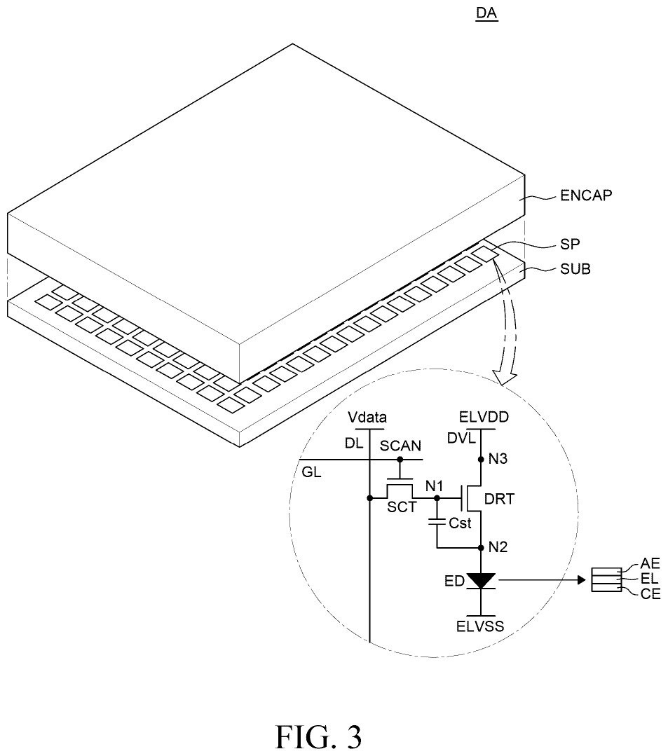

FIG. 3 is an equivalent circuit diagram of the subpixel of the display panel according to the embodiment of the present specification.

The subpixels SP, which are disposed in the normal area NA, the first optical area DA1, and the second optical area DA2 included in the display area DA of the display panel DP, may each include a light-emitting element ED, a driving transistor DRT configured to operate the light-emitting element ED, a scan transistor SCT configured to transmit a data voltage VDATA to a first node N1 of the driving transistor DRT, and a storage capacitor Cst configured to maintain a predetermined voltage for one frame.

The driving transistor DRT may include the first node N1 to which the data voltage may be applied, a second node N2 electrically connected to the light-emitting element ED, and a third node N3 to which a drive voltage ELVDD is applied from a drive voltage line DVL. In the driving transistor DRT, the first node N1 may be a gate node, the second node N2 may be a source node or drain node, and the third node N3 may be a drain node or source node.

The light-emitting element ED may include an anode electrode AE, a light-emitting layer EL, and a cathode electrode CE. The anode electrode AE may be a pixel electrode disposed in each of the subpixels SP and electrically connected to the second node N2 of the driving transistor DRT of the subpixel SP. The cathode electrode CE may be a common electrode disposed in common in the plurality of subpixels SP, and a base voltage ELVSS may be applied to the cathode electrode CE.

For example, the anode electrode AE may be a pixel electrode, and the cathode electrode CE may be a common electrode. On the contrary, the anode electrode AE may be a common electrode, and the cathode electrode CE may be a pixel electrode. Hereinafter, for convenience of description, it is assumed that the anode electrode AE is a pixel electrode, and the cathode electrode CE is a common electrode.

In case that the light-emitting element ED is an organic light-emitting diode, the light-emitting layer EL of the light-emitting element ED may include an organic light-emitting layer including an organic material.

The scan transistor SCT is turned on or off by being controlled in response to a scan signal SCAN that is a gate signal applied through the gate line GL. The scan transistor SCT may be electrically connected between the first node N1 of the driving transistor DRT and the data line DL.

The storage capacitor Cst may be electrically connected between the first node N1 and the second node N2 of the driving transistor DRT.

As illustrated in FIG. 3, the subpixels SP may each have a 2T (transistor) 1C (capacitor) structure including two transistors DRT and SCT and a single capacitor Cst. In some instances, the subpixel SP may further include one or more transistors or further include one or more capacitors.

The storage capacitor Cst is not a parasitic capacitor (e.g., Cgs or Cgd) that is an internal capacitor that may be present between the first node N1 and the second node N2 of the driving transistor DRT. However, the storage capacitor Cst may be an external capacitor intentionally designed outside the driving transistor DRT.

The driving transistor DRT and the scan transistor SCT may each be an n-type transistor or a p-type transistor.

The circuit element (particularly, the light-emitting element ED) in each of the subpixels SP is vulnerable to outside moisture or oxygen. Therefore, an encapsulation layer ENCAP may be disposed on the display panel DP in order to inhibit outside moisture or oxygen from penetrating into the circuit element (particularly, the light-emitting element ED). The encapsulation layer ENCAP may be disposed in a shape that covers the light-emitting elements ED.

Meanwhile, a differential pixel density designing method may be applied as one method of increasing the transmittance of at least one of the first optical area DA1 and the second optical area DA2. According to the differential pixel density designing method, the display panel DP may be designed so that the number of subpixels per unit area in at least one of the first optical area DA1 and the second optical area DA2 is smaller than the number of subpixels per unit area in the normal area NA.

However, in some instances, alternatively, a differential pixel size designing method may be applied as another method of increasing the transmittance of at least one of the first optical area DA1 and the second optical area DA2. According to the differential pixel size designing method, the display panel DP may be designed so that the number of subpixels per unit area in at least one of the first optical area DA1 and the second optical area DA2 is equal or similar to the number of subpixels per unit area in the normal area NA, and a size (i.e., light-emitting area size) of each of the subpixels SP disposed in at least one of the first optical area DA1 and the second optical area DA2 is smaller than a size (i.e., light-emitting area size) of each of the subpixels SP disposed in the normal area NA.

Hereinafter, for convenience of description, the description will be made on the assumption that the differential pixel density designing method is applied between the two types of methods (the differential pixel density designing method and the differential pixel size designing method) of increasing the transmittance of at least one of the first optical area DA1 and the second optical area DA2.

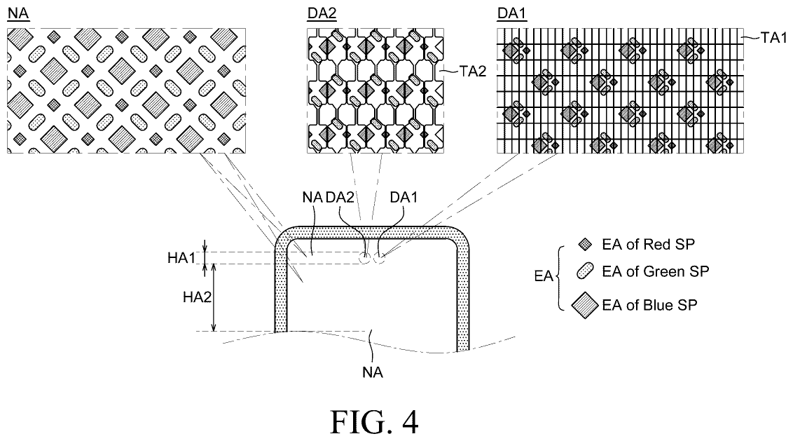

FIG. 4 is a view illustrating an example in which the subpixels are disposed in the display area according to the embodiment of the present specification.

FIG. 4 illustrates the arrangement of the subpixels SP in the three types of areas NA, DA1, and DA2 included in the display area DA of the display panel according to the embodiment of the present specification.

With reference to FIG. 4, the plurality of subpixels SP may be disposed in each of the normal area NA, the first optical area DA1, and the second optical area DA2 included in the display area.

For example, the plurality of subpixels SP may include a red subpixel Red SP configured to emit red light, a green subpixel Green SP configured to emit green light, and a blue subpixel Blue SP configured to emit blue light.

Therefore, the normal area NA, the first optical area DA1, and the second optical area DA2 may each include a light-emitting area EA for the red subpixel Red SP, a light-emitting area EA for the green subpixel Green SP, and a light-emitting area EA for the blue subpixel Blue SP.

With reference to FIG. 4, the normal area NA may include the light-emitting area EA without including the light transmission structure.

However, the first optical area DA1 and the second optical area DA2 need to include the light transmission structure while including the light-emitting area EA.

Therefore, the first optical area DA1 may include the light-emitting area EA and a first transmissive area TA1, and the second optical area DA2 may include the light-emitting area EA and a second transmissive area TA2.

The light-emitting area EA and the transmissive areas TA1 and TA2 may be distinguished depending on whether light may be transmitted. That is, the light-emitting area EA may be an area that cannot transmit light, and the transmissive areas TA1 and TA2 may be areas that may transmit light.

In addition, the light-emitting area EA and the transmissive areas TA1 and TA2 may be distinguished depending on whether a particular metal layer is formed. For example, a cathode electrode may be formed in the light-emitting area EA, but no cathode electrode may be formed in the transmissive areas TA1 and TA2. In addition, a light-blocking layer may be formed in the light-emitting area EA, but no light-blocking layer may be formed in the transmissive areas TA1 and TA2.

In the transmissive areas TA1 and TA2, an anti-deposition layer (not illustrated) made of an organic material may be disposed on the same plane as the cathode electrode. During a process of forming the cathode electrode, a cathode electrode material is not deposited on the anti-deposition layer, such that the cathode electrode may be selectively formed on the substrate SUB.

The first optical area DA1 includes the first transmissive area TA1, and the second optical area DA2 includes the second transmissive area TA2, such that both the first optical area DA1 and the second optical area DA2 may transmit light.

The transmittance (degree of light transmission) of the first optical area DA1 and the transmittance (degree of light transmission) of the second optical area DA2 may be equal to each other.

In this case, the first transmissive area TA1 of the first optical area DA1 and the second transmissive area TA2 of the second optical area DA2 may be identical in shape or size. Alternatively, even though the first transmissive area TA1 of the first optical area DA1 and the second transmissive area TA2 of the second optical area DA2 are different in shape or size, a proportion of the first transmissive area TA1 in the first optical area DA1 and a proportion of the second transmissive area TA2 in the second optical area DA2 may be equal to each other.

Alternatively, the transmittance (degree of light transmission) of the first optical area DA1 and the transmittance (degree of light transmission) of the second optical area DA2 may be different from each other.

In this case, the first transmissive area TA1 of the first optical area DA1 and the second transmissive area TA2 of the second optical area DA2 may be different in shape or size. Alternatively, even though the first transmissive area TA1 of the first optical area DA1 and the second transmissive area TA2 of the second optical area DA2 are identical in shape or size, a proportion of the first transmissive area TA1 in the first optical area DA1 and a proportion of the second transmissive area TA2 in the second optical area DA2 may be different from each other.

For example, in case that the first electronic optical device, which overlaps with the first optical area DA1, is a camera and the second electronic optical device, which overlaps with the second optical area DA2, is a detection sensor, the camera may require a larger light amount than the detection sensor.

Therefore, the transmittance (degree of light transmission) of the first optical area DA1 may be higher than the transmittance (degree of light transmission) of the second optical area DA2.

In this case, the first transmissive area TA1 of the first optical area DA1 may have a larger size than the second transmissive area TA2 of the second optical area DA2. Alternatively, even though the first transmissive area TA1 of the first optical area DA1 and the second transmissive area TA2 of the second optical area DA2 are identical in size, a proportion of the first transmissive area TA1 in the first optical area DA1 may be larger than a proportion of the second transmissive area TA2 in the second optical area DA2.

Hereinafter, for convenience of description, an example will be described in which the transmittance (degree of light transmission) of the first optical area DA1 is higher than the transmittance (degree of light transmission) of the second optical area DA2.

In the embodiment of the present specification, the transmissive areas TA1 and TA2 illustrated in FIG. 4 may each be referred to as a transparent area, and the transmittance may be referred to as transparency.

In the embodiment of the present specification, as illustrated in FIG. 4, it is assumed that the first optical area DA1 and the second optical area DA2 are positioned at an upper end of the display area of the display panel and disposed side by side in a leftward/rightward direction.

With reference to FIG. 4, a horizontal display area, in which the first optical area DA1 and the second optical area DA2 are disposed, is referred to as a first horizontal display area HA1, and a horizontal display area, in which the first optical area DA1 and the second optical area DA2 are not disposed, is referred to as a second horizontal display area HA2.

The first horizontal display area HA1 may include the normal area NA, the first optical area DA1, and the second optical area DA2. In contrast, the second horizontal display area HA2 may include only the normal area NA.

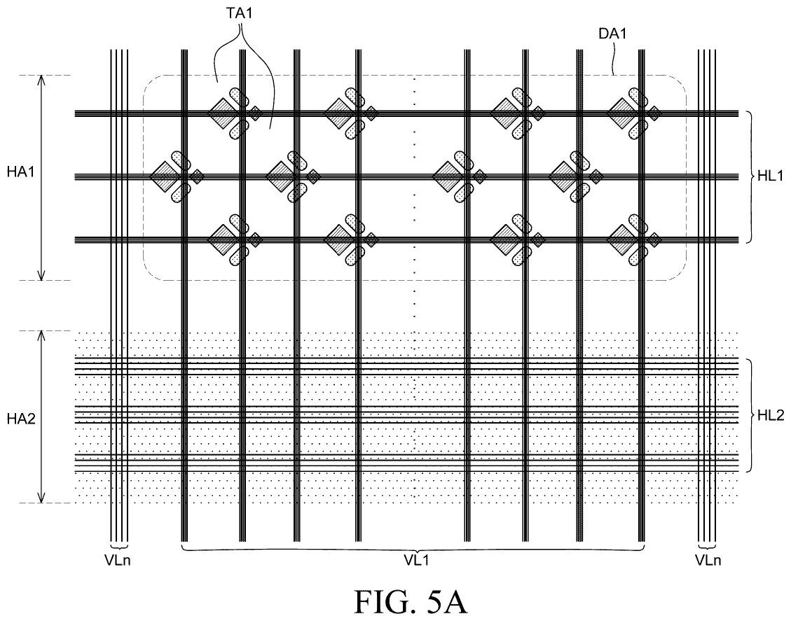

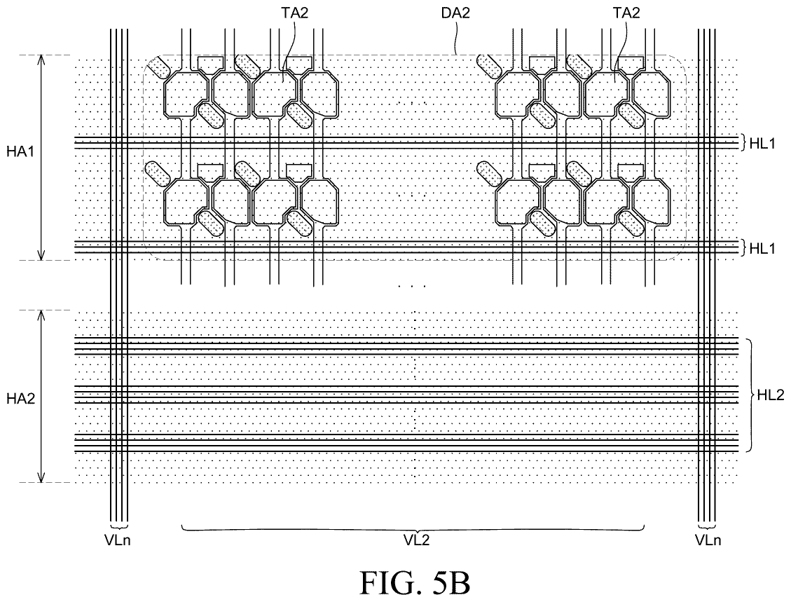

FIG. 5A is a view illustrating an example in which signal lines are disposed in the first optical area and the normal area according to the embodiment of the present specification. FIG. 5B is a view illustrating an example in which the signal lines are disposed in the second optical area and the normal area according to the embodiment of the present specification.

FIG. 5A illustrates the arrangement of the signal lines in the first optical area DA1 and the normal area NA of the display panel DP according to the embodiment of the present specification. FIG. 5B illustrates the arrangement of the signal lines in the second optical area DA2 and the normal area NA of the display panel DP according to the embodiment of the present specification.

FIG. 5A illustrates a part of the first horizontal display area HA1 and a part of the first optical area DA1. FIG. 5B illustrates a part of the second horizontal display area HA2 and a part of the second optical area DA2. In addition, as illustrated in FIGS. 5A and 5B, the first horizontal display area HA1 includes the normal area, the first optical area DA1, and the second optical area DA2, and the second horizontal display area HA2 includes only the normal area.

Various types of horizontal lines HL1 and HL2 and various types of vertical lines VLn, VL1, and VL2 may be disposed on the display panel DP.

In the embodiment of the present specification, a horizontal direction and a vertical direction may mean two directions intersecting each other. The horizontal direction and the vertical direction may be different from each other in a viewing direction. For example, in the embodiment of the present specification, the horizontal direction may mean a direction in which one gate line is disposed while extending, and the vertical direction may mean a direction in which one data line is disposed while extending.

With reference to FIGS. 5A and 5B, horizontal lines disposed on the display panel DP may include a first horizontal line HL1 disposed in the first horizontal display area HA1, and a second horizontal line HL2 disposed in the second horizontal display area HA2. In this case, the first horizontal line HL1 and the second horizontal line HL2 may each be the gate line. The gate line may include various types of gate lines in accordance with the structure of the subpixel.

With reference to FIGS. 5A and 5B, the vertical line disposed on the display panel DP may include a normal vertical line VLn disposed only in the normal area, a first vertical line VL1 configured to pass through both the first optical area DA1 and the normal area, and a second vertical line VL2 configured to pass through both the second optical area DA2 and the normal area.

The vertical line disposed on the display panel DP may include a data line, a drive voltage line, and the like. Further, the vertical line may further include a reference voltage line, an initialization voltage line, and the like. That is, the normal vertical line VLn, the first vertical line VL1, and the second vertical line VL2 may each include the data line, the drive voltage line, and the like and further include the reference voltage line, the initialization voltage line, and the like.

In the embodiment of the present specification, the term “horizontal” used in the horizontal line merely means that a signal is transmitted from the left side (or right side) to the right side (or left side) but does not mean that the horizontal line extends in a straight shape only in an accurately horizontal direction. That is, FIGS. 5A and 5B illustrate that the first horizontal line HL1 and the second horizontal line HL2 each have a straight shape. However, at least one of the first horizontal line HL1 and the second horizontal line HL2 may include a bent or curved portion.

In the embodiment of the present specification, the term “vertical” in the vertical line merely means that a signal is transmitted from the upper side (or lower side) to the lower side (or upper side) but does not mean that the vertical line extends in a straight shape only in an accurately vertical direction. That is, FIGS. 5A and 5B illustrate that the normal vertical line VLn, the first vertical line VL1, and the second vertical line VL2 each have a straight shape. However, at least one of the normal vertical line VLn, the first vertical line VL1, and the second vertical line VL2 may include a bent or curved portion.

With reference to FIGS. 4 and 5A, the first optical area DA1 included in the first horizontal area HA1 may include the light-emitting area EA and the first transmissive area TA1. In the first optical area DA1, an outer area of the first transmissive area TA1 may include the light-emitting area EA.

With reference to FIG. 5A, in order to improve the transmittance of the first optical area DA1, the first horizontal line HL1 passing through the first optical area DA1 may extend while bypassing the first transmissive area TA1 in the first optical area DA1. Therefore, the first horizontal line HL1 passing through the first optical area DA1 may include a curved section, a bending section, or the like that bypasses a portion disposed outside an outer peripheral rim of the first transmissive area TA1. The first horizontal line HL1, which passes through the first optical area DA1, and the second horizontal line HL2, which does not pass through the first optical area DA1, may be different in shape or length.

In addition, in order to improve the transmittance of the first optical area DA1, the first vertical line VL1 passing through the first optical area DA1 may extend while bypassing the first transmissive area TA1 in the first optical area DA1. Therefore, the first vertical line VL1 passing through the first optical area DA1 may include a curved section, a bending section, or the like that bypasses a portion disposed outside an outer peripheral rim of the first transmissive area TA1. The first vertical line VL1, which passes through the first optical area DA1, and the normal vertical line VLn, which is disposed in the normal area NA without passing through the first optical area DA1, may be different in shape or length.

With reference to FIG. 5A, the first transmissive areas TA1 included in the first optical area DA1 in the first horizontal area HA1 may be arranged in an oblique direction.

With reference to FIG. 5A, the light-emitting area may be disposed between the two first transmissive areas TA1, which are disposed adjacent to each other in the leftward/rightward direction, in the first optical area DA1 in the first horizontal area HA1. The light-emitting area may be disposed between the two first transmissive areas, which are disposed adjacent to each other in the upward/downward direction, in the first optical area DA1 in the first horizontal area HA1.

With reference to FIGS. 4 and 5B, the second optical area DA2 included in the first horizontal area HA1 may include the light-emitting area EA and the second transmissive area TA2. In the second optical area DA2, an outer area of the second transmissive area TA2 may include the light-emitting area EA.

As illustrated in FIG. 5B, the positions and arrangement states of the light-emitting area EA and the second transmissive area TA2 in the second optical area DA2 may be different from the positions and arrangement states of the light-emitting area EA and the first transmissive area TA1 in the first optical area DA1 in FIG. 5A. However, the positions and arrangement states of the light-emitting area EA and the second transmissive area TA2 in the second optical area DA2 may be identical to the positions and arrangement states of the light-emitting area EA and the first transmissive area TA1 in the first optical area DA1 in FIG. 5A.

With reference to FIG. 5B, the second transmissive areas TA2 may be arranged in the horizontal direction (leftward/rightward direction) in the second optical area DA2, and the light-emitting area EA may not be disposed between the two second transmissive areas TA2 adjacent to each other in the horizontal direction (leftward/rightward direction). In addition, the second transmissive areas TA2 may be arranged in the vertical direction (upward/downward direction) in the second optical area DA2, and the light-emitting area EA may be disposed between the second transmissive areas TA2 adjacent to each other in the vertical direction (upward/downward direction). That is, the light-emitting area EA may be disposed between the two rows of the second transmissive areas TA2.

The positions and arrangement states of the light-emitting area and the second transmissive area TA2 in the second optical area DA2 in FIG. 5B are different from the positions and arrangement states of the light-emitting area and the second transmissive area in the first optical area DA1 in FIG. 5A. Therefore, as illustrated in FIG. 5B, the first horizontal line HL1 may pass through the second optical area DA2 in the first horizontal area HA1 and the normal area at the periphery of the second optical area DA2 in a shape different from the shape illustrated in FIG. 5A. However, the first horizontal line HL1 may pass through the second optical area DA2 in the first horizontal area HA1 and the normal area at the periphery of the second optical area DA2 in the same shape as illustrated in FIG. 5A.

With reference to FIG. 5B, when the first horizontal line HL1 passes through the second optical area DA2 in the first horizontal area HA1 and the normal area NA at the periphery of the second optical area DA2, the first horizontal line HL1 may pass in a straight shape, without having a curved section or a bending section, between the second transmissive areas TA2 disposed adjacent to each other in the upward/downward direction.

For example, one first horizontal line HL1 has a curved section or a bending section in the first optical area DA1 but may not have a curved section or a bending section in the second optical area DA2.

In addition, in order to improve the transmittance of the second optical area DA2, the second vertical line VL2 passing through the second optical area DA2 may extend while bypassing the second transmissive area TA2 in the second optical area DA2. As illustrated in FIG. 5B, the second vertical line VL2 passing through the second optical area DA2 may include a curved section, a bending section, or the like that bypasses a portion disposed outside an outer peripheral rim of the second transmissive area TA2. Therefore, the second vertical line VL2, which passes through the second optical area DA2, and the normal vertical line VLn, which is disposed in the normal area without passing through the second optical area DA2, may be different in shape or length.

In case that the first horizontal line HL1 passing through the first optical area DA1 have curved sections or bending sections that bypass the portion disposed outside the outer peripheral rim of the first transmissive area TA1, a length of the first horizontal line HL1 passing through the first optical area DA1 and the second optical area DA2 may be longer than a length of the second horizontal line HL2 disposed only in the normal area NA.

Therefore, resistance (hereinafter, referred to as ‘first resistance’) of the first horizontal line HL1, which passes through the first optical area DA1 and the second optical area DA2, may be higher than resistance (hereinafter, referred to as ‘second resistance’) of the second horizontal line HL2 disposed only in the normal area NA.

The first optical area DA1, which at least partially overlaps with the first electronic optical device 170a, includes the plurality of first transmissive areas TA1, and the second optical area DA2, which at least partially overlaps with the second electronic optical device 170b, includes the plurality of second transmissive areas TA2. Therefore, the number of subpixels, to which the first horizontal line HL1 passing through the first optical area DA1 and the second optical area DA2 is connected, may be different from the number of subpixels to which the second horizontal line HL2, which is disposed only in the normal area NA without passing through the first optical area DA1 and the second optical area DA2, is connected.

That is, the first optical area DA1 and the second optical area DA2 may be smaller in number of subpixels per unit area than the normal area NA.

The number (first number) of subpixels, to which the first horizontal line HL1 passing through the first optical area DA1 and the second optical area DA2 is connected, may be smaller than the number (second number) subpixels to which the second horizontal line HL2 disposed only in the normal area NA is connected.

A difference between the first number and the second number may vary depending on a difference between the resolution of each of the first optical area DA1 and the second optical area DA2 and the resolution of the normal area NA. For example, the difference between the first number and the second number may increase as the difference between the resolution of each of the first optical area DA1 and the second optical area DA2 and the resolution of the normal area NA increases.

Because the first number of subpixels, to which the first horizontal line HL1 passing through the first optical area DA1 and the second optical area DA2 is connected, is smaller than the second number of subpixels to which the second horizontal line HL2, which is disposed only in the normal area NA, is connected as described above, an area, in which the first horizontal line HL1 overlaps with other peripheral electrodes or lines, may be smaller than an area in which the second horizontal line HL2 overlaps with other peripheral electrodes or lines.

Therefore, the parasitic capacitance (hereinafter, referred to as first capacitance) formed between the first horizontal line HL1 and other peripheral electrodes or lines may be greatly lower than the parasitic capacitance (hereinafter, referred to as second capacitance) formed between the second horizontal line HL2 and other peripheral electrodes or lines.

In consideration of a high-low relationship between the first resistance and the second resistance (first resistance≥second resistance) and a high-low relationship between the first capacitance and the second capacitance (first capacitance<<second capacitance), a resistance-capacitance (RC) value (hereinafter, referred to as a first RC value) of the first horizontal line HL1 passing through the first optical area DA1 and the second optical area DA2 may be much smaller than an RC value (hereinafter, referred to as a second RC value) of the second horizontal line HL2 that is disposed only in the normal area without passing through the first optical area DA1 and the second optical area DA2 (i.e., first RC value<<second RC value).

The signal transmission properties through the first horizontal line HL1 and the signal transmission properties through the second horizontal line HL2 may be changed by a difference (hereinafter, referred to as an RC load deviation) between the first RC value of the first horizontal line HL1 and the second RC value of the second horizontal line HL2.

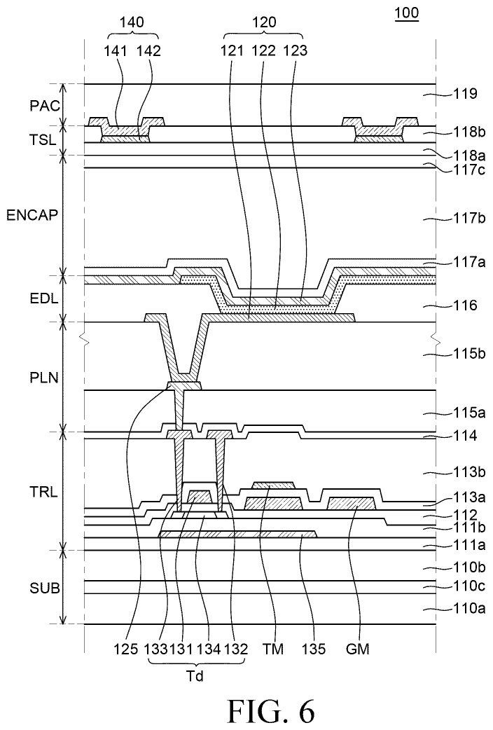

Hereinafter, a cross-sectional structure of the normal area NA of the organic light-emitting display device 100 according to the embodiment of the present specification will be described in detail with reference to FIG. 6.

FIG. 6 is a view illustrating a cross-sectional structure of one pixel disposed in the normal area according to the embodiment of the present specification.

In the normal area NA, a transistor layer TRL may be disposed above the substrate SUB, and a planarization layer PLN may be disposed above the transistor layer TRL. A light-emitting element layer EDL may be disposed above the planarization layer PLN, the encapsulation layer ENCAP may be disposed above the light-emitting element layer EDL, a touch sensing layer TSL may be disposed above the encapsulation layer ENCAP, and a protective layer PAC may be disposed above the touch sensing layer TSL. In addition, although not illustrated in FIG. 6, an organic material layer may be disposed above the protective layer PAC, and a polarizing layer may be disposed above the organic material layer.

The substrate SUB is a component for supporting various constituent elements included in the organic light-emitting display device 100 and may be made of an insulating material. The substrate SUB may include a first substrate 110a, a second substrate 110b, and an interlayer insulation film 110c. For example, the first substrate 110a and the second substrate 110b may each be a substrate made of polyimide (PI). The interlayer insulation film 110c may be disposed between the first substrate 110a and the second substrate 110b. As described above, the substrate SUB is configured by the first substrate 110a, the second substrate 110b, and the interlayer insulation film 110c, which may suppress moisture penetration.

In the normal area NA, various types of patterns 131, 132, 133, and 134 for forming transistors such as a driving transistor Td, various types of insulation films 111a, 111b, 112, 113a, 113b, and 114, and various types of metal patterns TM, GM, and 135 may be disposed on the transistor layer TRL.

Hereinafter, a layered structure of the transistor layer TRL will be described in more detail.

A multi-buffer layer 111a may be disposed on the second substrate 110b, and a metal layer 135 may be disposed on the multi-buffer layer 111a. In this case, the metal layer 135 may serve as a light shield and be also referred to as a light-blocking layer.

An active buffer layer 111b may be disposed on the multi-buffer layer 111a and the metal layer 135, and an active layer 134 of the driving transistor Td may be disposed on the active buffer layer 111b. For example, the active layer 134 may be made of polysilicon (p-Si), amorphous silicon (a-Si), or oxide semiconductor. However, the present specification is not limited thereto.

A gate insulation film 112 may be disposed on the active layer 134. The gate insulation film 112 may be made of silicon oxide (SiOx), silicon nitride (SiNx), or a multilayer thereof.

In addition, a gate electrode 131 of the driving transistor Td may be disposed on the gate insulation film 112. The gate electrode 131 may be disposed on the gate insulation film 112 and overlap with the active layer 134. The gate electrode 131 may be made of various electrically conductive materials, for example, magnesium (Mg), aluminum (Al), nickel (Ni), chromium (Cr), molybdenum (Mo), tungsten (W), gold (Au), or an alloy thereof. However, the present specification is not limited thereto.

A gate material layer GM may be disposed on the gate insulation film 112 and provided at a position different from a position at which the driving transistor Td is formed.

A first interlayer insulation film 113a may be disposed on the gate electrode 131 and the gate material layer GM. A metal pattern TM may be disposed on the first interlayer insulation film 113a. A second interlayer insulation film 113b may be disposed while covering the metal pattern TM disposed on the first interlayer insulation film 113a.

A source electrode 132 and a drain electrode 133 of the driving transistor Td may be disposed on the second interlayer insulation film 113b.

The source electrode 132 and the drain electrode 133 may be respectively connected to one side and the other side of a semiconductor layer 134 through contact holes provided in the second interlayer insulation film 113b, the first interlayer insulation film 113a, and the gate insulation film 112. The source electrode 132 and the drain electrode 133 may each be made of various electrically conductive materials, for example, magnesium (Mg), aluminum (Al), nickel (Ni), chromium (Cr), molybdenum (Mo), tungsten (W), gold (Au), or an alloy thereof. However, the present specification is not limited thereto.

A portion of the active layer 134, which overlaps with the gate electrode 131, is the channel area. One of the source electrode 132 and the drain electrode 133 is connected to one side of the channel area of the active layer 134, and the other of the source electrode 132 and the drain electrode 133 is connected to the other side of the channel area of the active layer 134.

A passivation layer 114 may be disposed on the source electrode 132 and the drain electrode 133. The passivation layer 114 may serve to protect the driving transistor Td and be made of an inorganic film, for example, silicon oxide (SiOx), silicon nitride (SiNx), or a multilayer thereof.

The planarization layer PLN may be positioned above the transistor layer TRL. The planarization layer PLN may include a first planarization layer 115a and a second planarization layer 115b. The planarization layer PLN protects the driving transistor Td and planarizes an upper portion of the driving transistor Td. The first planarization layer 115a may be disposed on the passivation layer 114, and a connection electrode 125 may be disposed on the first planarization layer 115a.

The connection electrode 125 may be connected to one of the source electrode 132 and the drain electrode 133 through a contact hole provided in the first planarization layer 115a.

The second planarization layer 115b may be disposed on the connection electrode 125.

The light-emitting element layer EDL may be positioned above the second planarization layer 115b.

Hereinafter, a layered structure of the light-emitting element layer EDL will be described in detail.

The light-emitting element 120 including an anode 121, a light-emitting layer 122, and a cathode 123 may be formed on the second planarization layer 115b.

The anode 121 may be disposed on the second planarization layer 115b. In this case, the anode 121 may be electrically connected to the connection electrode 125 through a contact hole provided in the second planarization layer 115b. The anode 121 may be made of a metallic material.

In case that the organic light-emitting display device 100 is a top-emission type display device in which light emitted from the light-emitting element 120 propagates toward an upper side of the substrate SUB on which the light-emitting element 120 is disposed, the anode 121 may further include a transparent conductive layer, and a reflective layer disposed on the transparent conductive layer. For example, the transparent conductive layer may be made of transparent conductive oxide such as ITO or IZO. For example, the reflective layer may be made of silver (Ag), aluminum (Al), gold (Au), molybdenum (Mo), tungsten (W), chromium (Cr), or an alloy thereof.

A bank 116 may be disposed while covering the anode 121. In this case, a portion of the bank 116, which corresponds to the light-emitting area of the subpixel, may be opened. A part of the anode 121 may be exposed to the open area of the bank 116. The bank 116 may be made of an inorganic insulating material such as silicon nitride (SiNx) or silicon oxide (SiOx), or an organic insulating material such as benzocyclobutene-based resin, acrylic resin, or imide-based resin. However, the present specification is not limited thereto.

The light-emitting layer 122 may be disposed in the open area of the bank 116 and an area at the periphery of the open area. That is, the light-emitting layer 122 may be disposed on the anode 121 exposed through the open area of the bank 116. The light-emitting layer 122 may include a plurality of organic films.

The cathode 123 may be disposed on the light-emitting layer 122.

The encapsulation layer ENCAP may be positioned above the light-emitting element layer EDL.

The encapsulation layer ENCAP may have a single-layer or multilayer structure. For example, the encapsulation layer ENCAP may include a first encapsulation layer 117a, a second encapsulation layer 117b, and a third encapsulation layer 117c.

In this case, the first encapsulation layer 117a and the third encapsulation layer 117c may each be made of an inorganic film, and the second encapsulation layer 117b may be made of an organic film. Among the first encapsulation layer 117a, the second encapsulation layer 117b, and the third encapsulation layer 117c, the second encapsulation layer 117b may be thickest and serve as a planarization layer.

The first encapsulation layer 117a may be disposed on the cathode 123 and closest to the light-emitting element 120. The first encapsulation layer 117a may be made of an inorganic insulating material that may be deposited at a low temperature. For example, the first encapsulation layer 117a may be made of silicon nitride (SiNx), silicon oxide (SiOx), silicon oxynitride (SiON), aluminum oxide (Al₂O₃), or the like. Because the first encapsulation layer 117a is deposited in a low-temperature ambience, it is possible to suppress damage to the light-emitting layer 122 made of an organic material vulnerable to a high-temperature ambience during a deposition process.

The second encapsulation layer 117b may have a smaller area than the first encapsulation layer 117a. In this case, the second encapsulation layer 117b may be formed to expose two opposite ends of the first encapsulation layer 117a. The second encapsulation layer 117b may serve as a buffer for mitigating stress between the layers caused when the flexible display device is bent. The second encapsulation layer 117b may serve to improve the planarization performance.

For example, the second encapsulation layer 117b may be made of an organic insulating material such as acrylic resin, epoxy resin, polyimide, polyethylene, or silicon oxycarbon (SiOC). For example, the second encapsulation layer 117b may also be formed in an inkjet manner. However, the present specification is not limited thereto.

The third encapsulation layer 117c may be formed above the substrate SUB having the second encapsulation layer 117b to cover a top surface and a side surface of each of the second encapsulation layer 117b and the first encapsulation layer 117a. In this case, the third encapsulation layer 117c may minimize or block the penetration of outside moisture or oxygen into the first encapsulation layer 117a and the second encapsulation layer 117b. For example, the third encapsulation layer 117c may be made of an inorganic insulating material such as silicon nitride (SiNx), silicon oxide (SiOx), silicon oxynitride (SiON), or aluminum oxide (Al₂O₃).

Although not illustrated in FIG. 6, a color filter may be disposed on the encapsulation layer ENCAP. However, the present specification is not limited thereto.

The touch sensing layer TSL may be disposed above the encapsulation layer ENCAP.

A touch buffer film 118a may be disposed above the encapsulation layer ENCAP, a touch line 140 may be disposed on the touch buffer film 118a.

The touch line 140 may include a touch sensor metal 141 and a bridge metal 142 positioned on different layers. A touch interlayer insulation film 118b may be disposed between the touch sensor metal 141 and the bridge metal 142.

For example, the touch sensor metal 141 may include a first touch sensor metal, a second touch sensor metal, and a third touch sensor metal that are disposed adjacent to one another. The first touch sensor metal and the second touch sensor metal may be electrically connected to each other. However, in case that the third touch sensor metal is present between the first touch sensor metal and the second touch sensor metal, the first touch sensor metal and the second touch sensor metal may be electrically connected to each other through the bridge metal 142 present on a layer different from the layer on which the first touch sensor metal and the second touch sensor metal are disposed. The bridge metal 142 may be insulated from a third touch sensor metal by the touch interlayer insulation film 118b.

During a process of forming the touch sensing layer TSL, a liquid chemical (a developer, an etching liquid, or the like) used for the process may be produced, or moisture or the like may be produced from the outside. Therefore, the touch buffer film 118a may be disposed, and the touch sensing layer TSL may be disposed on the touch buffer film 118a, which may inhibit moisture or a liquid chemical, which is produced during the process of manufacturing the touch sensing layer TSL, from penetrating into the light-emitting layer 122 including an organic material.

As describe above, the touch buffer film 118a may suppress damage to the light-emitting layer 122 vulnerable to a liquid chemical or moisture. To suppress damage to the light-emitting layer 122 including an organic material vulnerable to a high temperature, the touch buffer film 118a may be made of an organic insulating material that may be formed at a predetermined low temperature (e.g., 100° C. or less) and have low permittivity of 1 to 3. For example, the touch buffer film 118a may be made of an acrylic-based, epoxy-based, or siloxane-based material.

The organic light-emitting display device 100 according to the embodiment of the present specification may be a flexible display device. When the flexible display device is bent, the encapsulation layer ENCAP may be damaged. In this case, the touch sensor metal 141 positioned above the touch buffer film 118a may be broken. Therefore, the touch buffer film 118a according to the embodiment of the present specification is made of an organic insulating material and has the planarization performance. Therefore, it is possible to suppress damage to the encapsulation layer ENCAP and inhibit the metals 141 and 142, which constitute the touch line 140, from being broken even though the flexible display device is bent.

The protective layer PAC (119) may be disposed to cover the touch line 140. The protective layer 119 may be made of an organic insulation film.

Although not illustrated in FIG. 6, the polarizing layer may be disposed on the protective layer PAC (119). The polarizing layer suppresses the reflection of external light in the display area DA of the substrate SUB. In case that the organic light-emitting display device 100 is used outside, external natural light may be introduced and reflected by the reflective layer included in the anode 121 of the light-emitting element or reflected by an electrode made of metal and disposed below the light-emitting element 120. The light beams, which are reflected as described above, may inhibit an image on the organic light-emitting display device 100 from being visually recognized. The polarizing layer may polarize, in a particular direction, the light introduced from the outside, thereby inhibiting the reflected light from being discharged again to the outside of the organic light-emitting display device 100.

In addition, although not illustrated in FIG. 6, a cover glass may be bonded onto the polarizing layer by a bonding layer. The bonding layer may serve to bond the constituent elements of the organic light-emitting display device 100. For example, the bonding layer may be formed by using a bonding agent for an optically transparent display such as a pressure-sensitive bonding agent, an optically transparent bonding agent (optical clear adhesive (OCR)), or an optically transparent resin (optical clear resin (OCR)). However, the present specification is not limited thereto. The cover glass may protect the constituent elements of the organic light-emitting display device 100 from external impact and suppress damage such as scratches.

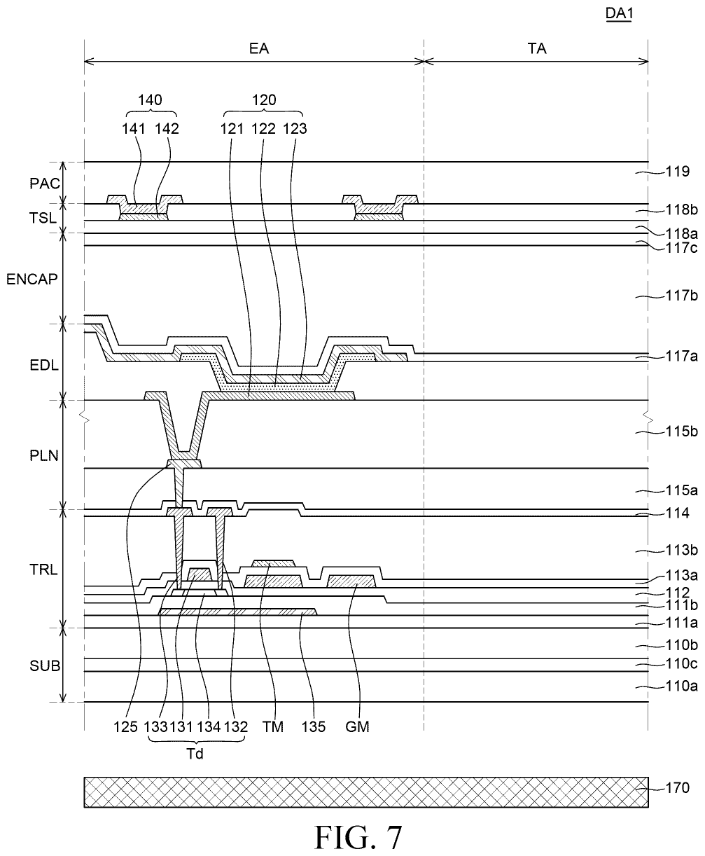

Hereinafter, a cross-sectional structure of the optical area of the organic light-emitting display device 100 according to the embodiment of the present specification will be described in detail with reference to FIG. 7.

Hereinafter, for convenience of description, an example will be described in which the display area DA of the display panel DP of the organic light-emitting display device 100 includes the normal area NA and the first optical area DA1 (i.e., FIGS. 1A and 1B). However, the description of the first optical area DA1 may also be equally applied to the second optical area DA2.

FIG. 7 is a view illustrating a cross-sectional structure of the light-emitting area and the transmissive area of the optical area according to the embodiment of the present specification.

With reference to FIG. 7, the first optical area DA1 includes the light-emitting area EA and a transmissive area TA.

The light-emitting area EA and the transmissive area TA of the first optical area DA1 may each basically include the substrate SUB, the transistor layer TRL, the planarization layer PLN, the light-emitting element layer EDL, the encapsulation layer ENCAP, the touch detection layer TSL, and the protective layer PAC. In this case, the electronic optical device 170 may be disposed below the substrate SUB in the first optical area DA1.

The substrate SUB, the transistor layer TRL, the planarization layer PLN, the light-emitting element layer EDL, the encapsulation layer ENCAP, the touch detection layer TSL, and the protective layer PAC included in the first optical area DA1 are substantially identical to the constituent element having the same reference numerals and disposed in the normal area NA of the display panel DP described above with reference to FIG. 6. Therefore, a repeated description thereof will be omitted. In addition, because the light-emitting area EA of the first optical area DA1 is substantially identical in structure to the normal area NA of the display panel DP, a repeated description thereof will be omitted.

Hereinafter, the transmissive area TA disposed in the first optical area DA1 will be described.

The substrate SUB and various types of insulation films 111a, 111b, 112, 113a, 113b, 114, 115a, 115b, 117a, 117b, 117c, and PAC disposed in the light-emitting area EA of the first optical area DA1 may also be disposed in the transmissive area TA of the first optical area DA1 in the same manner.

However, other than the insulating material disposed in the light-emitting area EA of the first optical area DA1, a material layer having electrical or opaque properties may not be disposed in the transmissive area TA of the first optical area DA1.

For example, the metallic material layers 135, 131, GM, TM, 132, 133, and 125 and the semiconductor layer 134 related to the transistor are not disposed in the transmissive area TA. The anode 121 included in the light-emitting element 120 may not be disposed in the transmissive area TA. The cathode 123 may not be disposed in an area, except for a partial area adjacent to the light-emitting area EA in the transmissive area TA. The light-emitting layer 122 may or may not be disposed in the transmissive area TA. The touch sensor metal 141 and the bridge metal 142 included in the touch sensor may not be disposed in the transmissive area TA.

Because the transmissive area TA in the first optical area DA1 overlaps with the electronic optical device 170, the transmittance of the transmissive area TA, which allows the electronic optical device 170 to normally operate, needs to be ensured. According to the embodiment of the present specification, the cathode 123 is not disposed in the transmissive area TA in order to ensure the transmittance of the transmissive area TA.

In order to implement this configuration, the anti-deposition layer (not illustrated) may be made of an organic material may be disposed on the planarization layer 115b and the light-emitting layer 122 of the transmissive area TA. The anti-deposition layer serves to suppress deposition of the cathode 123. During a process of forming the cathode electrode, a cathode electrode material is not deposited on the anti-deposition layer, such that the cathode electrode may be selectively formed on the substrate SUB. For example, the anti-deposition layer may be deposited while corresponding to the transmissive area TA by using a fine metal mask (FMM). Specifically, the FMM may be positioned to expose the transmissive area TA, and then the anti-deposition layer may be formed. In case that the cathode 123 is deposited after the anti-deposition layer is disposed on the light-emitting layer 122 in the transmissive area TA, the cathode 123 may not be deposited in an area, in which the anti-deposition layer is disposed, because a bonding force between the anti-deposition layer and the layer disposed above the anti-deposition layer is low.

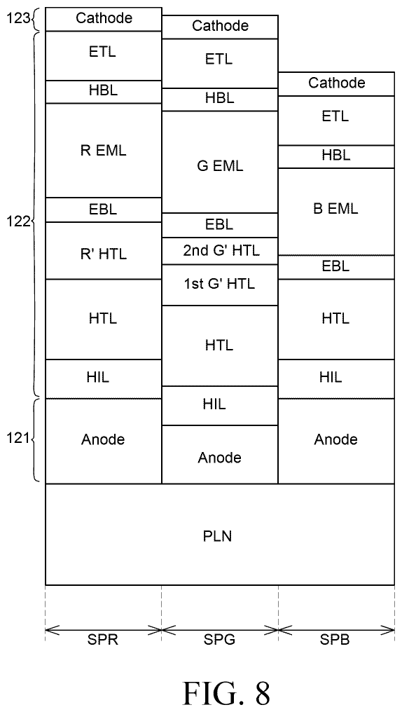

Hereinafter, the structure of the light-emitting layer 122, which constitutes the light-emitting element 120 of the organic light-emitting display device 100 according to the embodiment of the present specification, will be described in detail with reference to FIG. 8.

FIG. 8 is a schematic view of one pixel of the organic light-emitting display device 100 according to the embodiment of the present specification.

As illustrated in FIG. 8, one pixel of the organic light-emitting display device 100 according to the embodiment of the present specification may include a first subpixel, a second subpixel, and a third subpixel. In this case, the first subpixel, the second subpixel, and the third subpixel may be red, green, and blue subpixels SPR, SPG, and SPB, respectively. For example, as described with reference to FIG. 6, the normal area NA and the optical areas DA1 and DA2 of the display panel DP according to the embodiment of the present specification may each include the red subpixel SPR configured to emit red light, the green subpixel SPG configured to emit green light, and the blue subpixel SPB configured to emit blue light.

With reference to FIG. 8, in the organic light-emitting display device 100 according to the embodiment of the present specification, the red, green, and blue subpixels SPR, SPG, and SPB may each include the light-emitting element including the anode 121, the light-emitting layer 122, and the cathode 123.

More specifically, the anode 121 is formed on the planarization layer PLN for each of the red, green, and blue subpixels SPR, SPG, and SPB. The anodes 121 of the red, green, and blue subpixels SPR, SPG, and SPB are separated. Thicknesses of the anodes 121 of the red, green, and blue subpixels SPR, SPG, and SPB may be different.

Specifically, with reference to FIG. 8, the anode 121 disposed in the green subpixel SPG may have a smaller thickness than the anodes 121 disposed in the red subpixel SPR and the blue subpixel SPB. As described below, the anode 121 disposed in the green subpixel SPG may have a smaller thickness than the anodes 121 disposed in the red subpixel SPR and the blue subpixel SPB to compensate for thicknesses of a second auxiliary hole transport layer 1st G′HTL and a third auxiliary hole transport layer 2nd G′HTL disposed in the green subpixel SPG.

The light-emitting layer 122 is disposed on the anode 121. The light-emitting layer 122 includes a hole injection layer HIL, a hole transport layer HTL, an auxiliary hole transport layer, an electron blocking layer EBL, an organic light-emitting layer EML, a hole blocking layer HBL, and an electron transport layer ETL sequentially positioned from above the anode 121.

The hole injection layer HIL serves to smoothly inject positive holes into the organic light-emitting layer from the anode 121. The hole injection layer HIL may be formed in common in the red, green, and blue subpixels SPR, SPG, and SPB. The hole injection layer HIL may be selected from a group consisting of arylamine bases, i.e., NATA, 2T-NATA, and NPNPB, and P-doped systems, i.e., F4-TCNQ and PPDN. However, the present specification is not limited thereto.

The hole transport layer HTL serves to smoothly inject positive holes into the organic light-emitting layer from the anode 121. The hole transport layer HTL may be formed in common in the red, green, and blue subpixels SPR, SPG, and SPB. The hole transport layer HTL may be selected from a group consisting of arylamine bases, i.e., TPD (N,N′-bis-(3-methylphenyl)-N,N′-bis-(phenyl)-benzidine), PPD, TTBND, FFD, p-dmDPS, and TAPC, Starbust aromatic amines, i.e., TCTA, PTDATA, TDAPB, TDBA, 4-a, and TCTA, Spiro and Ladder Type substances, i.e., Spiro-TPD, Spiro-mTTB, and Spiro-2, NPD (N,N-dinaphthyl-N,N′-diphenyl benzidine), s-TAD, and MTDATA (4,4′,4″-Tris(N-3-methylphenyl-N-phenyl-amino)-triphenylamine). However, the present specification is not limited thereto.

The auxiliary hole transport layers R′HTL, 1st G′HTL, and 2nd G′HTL may be formed only in the red subpixel SPR and the green subpixel SPG among the red, green, and blue subpixels SPR, SPG, and SPB on the hole transport layer HTL. The auxiliary hole transport layer is an optical auxiliary layer and adjusts a distance between the anode 121 and the cathode 123, i.e., the light-emitting layer 122. Therefore, the luminous efficiency may be further improved by a micro-cavity effect in which light emitted from the light-emitting layer 122 generates interference between the anode 121 and the cathode 123. The auxiliary hole transport layers R′HTL, 1st G′HTL, and 2nd G′HTL may be disposed above the hole transport layer HTL disposed as a common layer and serve to capture and trapping carriers generated by a leakage current. To this end, the auxiliary hole transport layers R′HTL, 1st G′HTL, and 2nd G′HTL may be made of a hole transportable material with a lower HOMO energy level than the hole transport layer HTL.

The auxiliary hole transport layers R′HTL, 1st G′HTL, and 2nd G′HTL include a first auxiliary hole transport layer R′HTL formed on the hole transport layer HTL of the red subpixel SPR, the second auxiliary hole transport layer 1st G′HTL and the third auxiliary hole transport layer 2nd G′HTL formed on the hole transport layer HTL of the green subpixel SPG.

The first auxiliary hole transport layer R′HTL adjusts an optical distance of a first organic light-emitting layer R EML, and a thickness of the first auxiliary hole transport layer R′HTL is adjusted on the basis of a wavelength of light emitted from the first organic light-emitting layer R EML. In addition, the second auxiliary hole transport layer 1st G′HTL and the third auxiliary hole transport layer 2nd G′HTL adjust an optical distance of a second organic light-emitting layer G EML, thicknesses of the second auxiliary hole transport layer 1st G′HTL and the third auxiliary hole transport layer 2nd G′HTL are adjusted on the basis of a wavelength of light emitted from the second organic light-emitting layer G EML. Because the electron transport layer ETL and the hole transport layer HTL are installed as common layers between the anode 121 and the first organic light-emitting layer R EML, an actual optical distance of the first organic light-emitting layer R EML may be determined depending on the first auxiliary hole transport layer R′HTL. Likewise, the optical distance of the second organic light-emitting layer G EML may be determined by the second auxiliary hole transport layer 1st G′HTL and the third auxiliary hole transport layer 2nd G′HTL. In this case, the thickness of the first auxiliary hole transport layer R′HTL of the red subpixel SPR may be larger than the thickness of the second auxiliary hole transport layer 1st G′HTL of the green subpixel SPG. However, the present specification is not limited thereto.

The second auxiliary hole transport layer 1st G′HTL is disposed on the hole transport layer HTL. The second auxiliary hole transport layer 1st G′HTL adjusts the optical distance of the second organic light-emitting layer G EML by increasing a distance between the anode 121 and the second organic light-emitting layer G EML.

The third auxiliary hole transport layer 2nd G′HTL is disposed between the second organic light-emitting layer G EML and the second auxiliary hole transport layer 1st G′HTL. The third auxiliary hole transport layer 2nd G′HTL may additionally increase the distance between the anode 121 and the second organic light-emitting layer G EML in comparison with a case in which only the second auxiliary hole transport layer 1st G′HTL is disposed in the green subpixel SPG. In this case, a position of a top surface of the anode 121 of the green subpixel SPG may be positioned to be lower than a position of top surfaces of the anodes 121 of the red subpixel SPR and the blue subpixel SPB by the thickness of the third auxiliary hole transport layer 2nd G′HTL. In comparison with a case in which one second auxiliary hole transport layer 1st G′HTL is used for the green subpixel SPG, the third auxiliary hole transport layer 2nd G′HTL is additionally disposed on the second auxiliary hole transport layer 1st G′HTL, and the position of the top surface of the anode 121 is positioned to be low to increase a distance by which light emitted downward from the second organic light-emitting layer G EML is reflected by the anode 121, such that the optical distance of the second organic light-emitting layer G EML may be increased. In general, in consideration of a formula related to capacitance (C=ε, C: capacitance, ε: dielectric constant, S: electrode area, d: distance between electrodes), the optical distance is increased by the third auxiliary hole transport layer 2nd G′HTL, and the capacitance of the green subpixel SPG is decreased. In case that the capacitance is decreased, the luminance of the green light-emitting element may be quickly decreased when the green light-emitting element is turned off, such that a falling delay time may be decreased, and a threshold voltage may be increased. Furthermore, the addition of the third auxiliary hole transport layer 2nd G′HTL may decrease the luminous efficiency of the green light during an operation with a low gradation. Therefore, during the operation with a low gradation, the luminance of the green subpixel SPG is higher than the luminance of the red and blue subpixels SPB, which may inhibit green light from being inadvertently emitted. A specific description related to the above-mentioned configuration will be described below with reference to Embodiments and Comparative Embodiment.

In order to slow movements of positive holes in the green subpixel SPG and increase the optical distance, the third auxiliary hole transport layer 2nd G′HTL may be made of a material having lower hole mobility (hole mobility) and a smaller refractive index than the material of the second auxiliary hole transport layer 1st G′HTL. For example, the hole mobility of the second auxiliary hole transport layer 1st G′HTL may be 10⁻⁴ to 5×10⁻⁶ [cm²/Vs] or 5.99×10⁻⁵ [cm²/Vs], and the hole mobility of the third auxiliary hole transport layer 2nd G′HTL may be 5×10⁻⁶ to 10⁻⁸ [cm²/Vs] or 2.11×10⁻⁷ [cm²/Vs]. In addition, a refractive index value of the third auxiliary hole transport layer 2nd G′HTL may be smaller by 0.05 to 0.2 than a refractive index value of the second auxiliary hole transport layer 1st G′HTL. More specifically, for example, the refractive index value of the second auxiliary hole transport layer 1st G′HTL may be 1.75 to 1.82, and the refractive index value of the third auxiliary hole transport layer 2nd G′HTL may be 1.70 to 1.75.

Meanwhile, a HOMO energy level of the third auxiliary hole transport layer 2nd G′HTL may be higher than a HOMO energy level of the second auxiliary hole transport layer 1st G′HTL. In addition, a LUMO energy level of the third auxiliary hole transport layer 2nd G′HTL may be higher than a LUMO energy level of the second auxiliary hole transport layer 1st G′HTL. For example, the HOMO energy level of the second auxiliary hole transport layer 1st G′HTL may be −5.16 to −5.22, the LUMO energy level of the second auxiliary hole transport layer 1st G′HTL may be −2.00 to −2.06, the HOMO energy level of the third auxiliary hole transport layer 2nd G′HTL may be −5.14 to −5.20, and the LUMO energy level of the third auxiliary hole transport layer 2nd G′HTL may be −1.87 to −1.93. However, the present specification is not limited thereto.

Meanwhile, in the organic light-emitting display device 100 according to the embodiment of the present specification, the third auxiliary hole transport layer 2nd G′HTL is additionally disposed on the second auxiliary hole transport layer 1st G′HTL to increase the optical distance of the green subpixel SPG and delay the movements of the positive holes. In this case, the top surface of the anode 121 of the green subpixel SPG is positioned to be lower than the top surfaces of the anodes 121 of the red subpixel SPR and the blue subpixel SPB to form a stepped portion to increase the distance between the anode 121 and the second organic light-emitting layer G EML and maintain the constant height of the light-emitting element by maintaining the distance between the second organic light-emitting layer G EML and the cathode 123. For example, with reference to FIG. 8A, the thickness of the anode 121 of the green subpixel SPG may be smaller than the thicknesses of the anodes 121 of the red subpixel SPR and the blue subpixel SPB. Therefore, a height difference between the top surface of the anode 121 of the green subpixel SPG and the top surfaces of the anodes 121 of the red subpixel SPR and the blue subpixel SPB may be 0.5 μm to 1.5 μm or 0.5 μm to 1.2 μm. Because the stepped portion is formed between the top surface of the anode 121 of the green subpixel SPG and the top surfaces of the anodes 121 of the red subpixel SPR and the blue subpixel SPB, a length of the hole transport layer HTL or the hole injection layer HIL, which is a common layer positioned above the anode 121, may be increased. Therefore, a movement distance of a leakage current through a common layer is increased, which may suppress a problem in which a light-emitting element of another subpixel emits light by a leakage current.

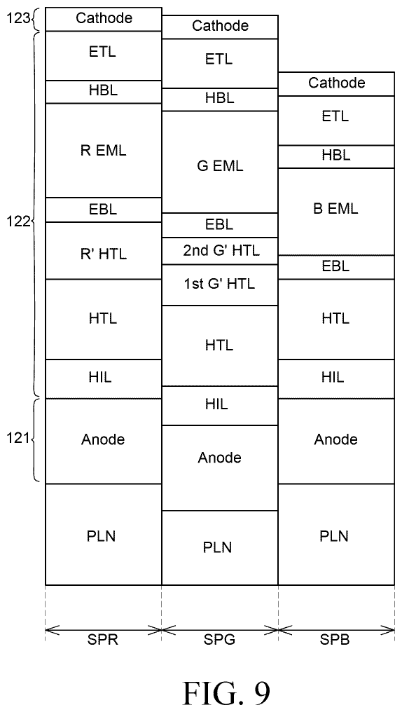

Meanwhile, in the organic light-emitting display device 100 according to another embodiment of the present specification, the thicknesses of the planarization layers PLN may be different to form a stepped portion on the top surface of the anode 121. With reference to FIG. 9, an organic light-emitting display device according to another embodiment of the present specification is substantially identical to the organic light-emitting display device 100 illustrated in FIG. 8, except that the structures of the planarization layers PLN and the anodes 121 are different. Therefore, repeated descriptions of the identical components will be omitted. Specifically, with reference to FIG. 9, a thickness of the planarization layer PLN of the green subpixel SPG may be smaller than thicknesses of the planarization layers PLN of the red subpixel SPR and the blue subpixel SPB. Therefore, the stepped portion may be formed so that the top surface of the anode 121 of the green subpixel SPG is disposed at a position lower than the top surfaces of the anodes 121 of the red subpixel SPR and the blue subpixel SPB.

The electron blocking layer EBL is disposed on the auxiliary hole transport layer or the hole transport layer HTL for each of the red, green, and blue subpixels SPR, SPG, and SPB. The electron blocking layer EBL inhibits electrons in first, second, and third organic light-emitting layers from moving to the hole transport layer HTL. The electron blocking layers EBL may be formed in common in the red, green, and blue subpixels SPR, SPG, and SPB and connected to one another. Alternatively, the electron blocking layers EBL of the red, green, and blue subpixels SPR, SPG, and SPB may be separated from one another. The HOMO energy level of the electron blocking layer may be −5.24 to −5.45, and the LUMO energy level of the electron blocking layer may be −1.43 to −1.63.

The first, second, and third organic light-emitting layers may be respectively disposed on the electron blocking layers EBL of the red, green, and blue subpixels SPR, SPG, and SPB. The first, second, and third organic light-emitting layers may include a material capable of emitting light in a visible ray range by receiving and combining positive holes and electrons.

The first, second, and third organic light-emitting layers may be formed in areas respectively corresponding to the red, green, and blue subpixels SPR, SPG, and SPB and divided into a red organic light-emitting layer, a green organic light-emitting layer, and a blue organic light-emitting layer. The organic light-emitting layers may have different thicknesses. A material known in the technical field may be used as the material of the light-emitting layer. For example, a material with good quantum efficiently for fluorescence or phosphorescence may be used as the material of the first, second, and third organic light-emitting layers.

The first, second, and third organic light-emitting layers may include a phosphorescent dopant material, a hole host material having a hole transport ability, and an electron host material having an electron transport ability. In general, the hole host material having the hole transport ability includes a carbazole based host, a triazine based host, and other hosts. For example, the hole host material includes α-NPD and TPD as an arylamine-based host, TDAPB and TCTA as a Starburst aromatic amine host, and spiro-TAD and OTP-1 as a Spiro and Ladder type host. In addition, the electron mobility of the hole host material having the hole transport ability has a value of 10⁻³ to 10⁻⁶ [cm²/Vs].

In addition, the electron host material having the electron transport ability includes a carbazole based host, a triazine based host, and other hosts. For example, the electron host material includes organometallic compounds, sulfone derivatives, oxazole, triazole derivatives, silole derivatives containing bipyridyl, phenyl benzimidazole containing compounds, and pyrene derivatives. In addition, the electron mobility of the electron host material having the electron transport ability has a value of 10⁻³ to 10⁻⁶ [cm²/Vs].

In case that the light-emitting layer material is the red organic light-emitting layer R EML as a specific example, the light-emitting layer material may be a phosphorescent material including a host material including CBP (carbazole biphenyl) or mCP(1,3-bis(carbazol-9-yl) and a dopant including any one or more materials selected from a group consisting of PIQIr(acac)(bis(1-phenylisoquinoline)acetylacetonate iridium), PQIr(acac)(bis(1-phenylquinoline)acetylacetonate iridium), BtP2Ir(acac), PQIr(tris(1-phenylquinoline)iridium), and PtOEP (octaethylporphyrin platinum). On the contrary, the light-emitting layer material may be a fluorescent material including PBD:Eu(DBM) 3(Phen) or Perylene. However, the present specification is not limited thereto.

In case that the light-emitting layer material is the green organic light-emitting layer G EML, the light-emitting layer material may be a phosphorescent material including a host material including CBP or mCP and including a dopant material including Ir(ppy)3(fac tris(2-phenylpyridine)iridium), Ir(ppy)2 (acac), and Ir(mpyp)3. On the contrary, the light-emitting layer material may be a fluorescent material including Alq3 (tris(8-hydroxyquinolino)aluminum). However, the present specification is not limited thereto.

In case that the light-emitting layer material is the blue organic light-emitting layer B EML, the light-emitting layer material may be a phosphorescent material including a host material including CBP or mCP and including a dopant material including (4,6-F2ppy)2Irpic, (F2ppy)2Ir(tmd), and Ir(dfppz)3. On the contrary, the light-emitting layer material may be a fluorescent material including any one selected from a group consisting of spiro-DPVBi, spiro-6P, distyryl-benzene (DSB), distrylarylene (DSA), PFO-based polymer, and PPV-based polymer. However, the present specification is not limited thereto.

The hole blocking layer HBL is disposed on the first, second, and third organic light-emitting layers. The hole blocking layer HBL inhibits the positive holes in the first, second, and third organic light-emitting layers from moving to the electron transport layer ETL. The hole blocking layers HBL may be formed in common in the red, green, and blue subpixels SPR, SPG, and SPB and connected to one another. Alternatively, the hole blocking layers HBL of the red, green, and blue subpixels SPR, SPG, and SPB may be separated from one another.

The electron transport layer ETL is disposed on the hole blocking layer HBL. The electron transport layer ETL serves to smoothly transport the electrons from the cathode 123 to the first, second, and third organic light-emitting layers. The electron transport layers ETL may be formed in common in the red, green, and blue subpixels SPR, SPG, and SPB and connected to one another. Alternatively, the electron transport layers ETL of the red, green, and blue subpixels SPR, SPG, and SPB may be separated from one another. The electron transport layer ETL may be made of any one or more materials selected from a group consisting of Alq3(tris(8-hydroxyquinolino) aluminum), PBD, TAZ, spiro-PBD, BAlq, and Salq. However, the present specification is not limited thereto.

The electron injection layer is disposed on the electron transport layer ETL. The electron injection layer serves to smoothly inject the electrons into the first, second, and third organic light-emitting layers from the cathode 123. The electron injection layer may be formed in common in the red, green, and blue subpixels SPR, SPG, and SPB and connected to one another. Alternatively, the electron injection layers of the red, green, and blue subpixels SPR, SPG, and SPB may be separated from one another. The electron injection layer may be made of LiF, Ba, or NaF. However, the present specification is not limited thereto.

Hereinafter, an effect achieved by the configurations of the second auxiliary hole transport layer 1st G′HTL and the third auxiliary hole transport layer 2nd G′HTL of the green subpixel SPG will be described more specifically with reference to Embodiments and Comparative Embodiment. However, the following embodiments are for exemplifying the present specification, and the scope of the present specification is not limited by the following embodiments.

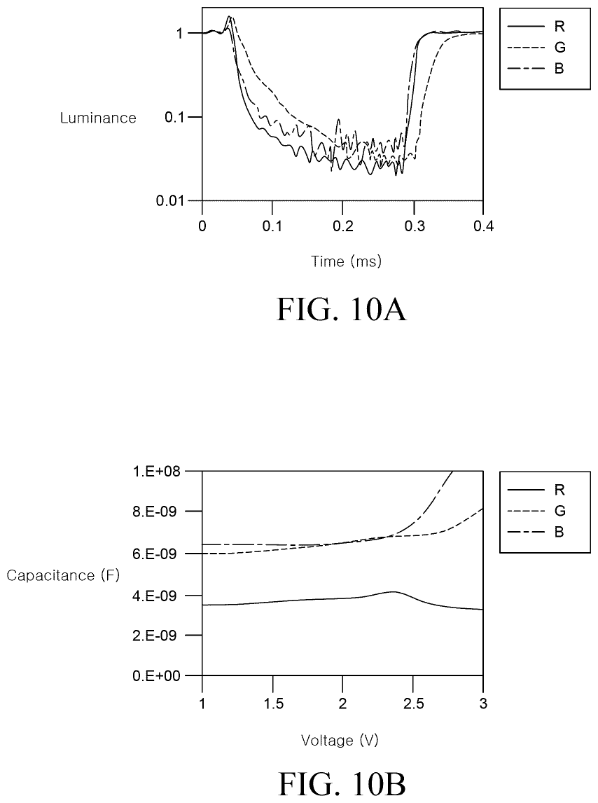

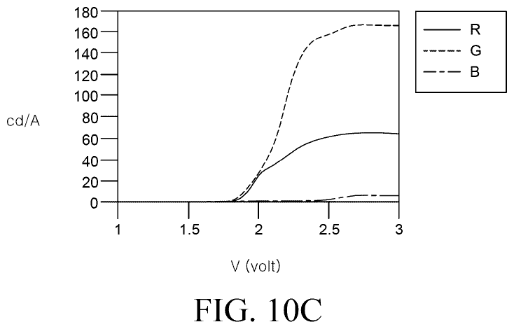

FIGS. 10A to 10C are graphs illustrating electrical properties of red, green, and blue subpixels SPR, SPG, and SPB according to Comparative Embodiment 1. FIG. 10A is a graph illustrating luminance properties over time of the red, green, and blue subpixels SPR, SPG, and SPB. FIG. 10B is a graph illustrating capacitance in accordance with drive voltages of the red, green, and blue subpixels SPR, SPG, and SPB. FIG. 10C is a graph illustrating luminance properties in accordance with drive voltages of the red, green, and blue subpixels SPR, SPG, and SPB.

In comparison with the organic light-emitting display device 100 illustrated in FIG. 8, Comparative Embodiment 1 in FIGS. 10A to 10C has a structure in which the first auxiliary hole transport layer R′HTL (HOMO energy level: 5.19, LUMO energy level: −2.03) of the green subpixel SPG has a thickness of 330 μm, but the second auxiliary hole transport layer 1st G′HTL is not formed.

First, with reference to FIG. 10A, it could be ascertained that when the luminance of the light-emitting element of each of the red, green, and blue subpixels SPR, SPG, and SPB was decreased from 1 to 0.1 level and the luminance was observed for 0 ms to 0.2 ms, a rising time and a falling time occurred in the order of the red, blue, and green light-emitting elements. More specifically, it could be ascertained that the rising time and the falling time of the red light-emitting element were respectively 18.9 μs and 27.5 μs, the rising time and the falling time of the blue light-emitting element were respectively 21.1 μs and 40.1 μs, and the rising time and the falling time of the green light-emitting element were respectively 45.8 μs and 77.3 μs. That is, it can be seen that there is a delay in falling and rising on the green light-emitting element. Therefore, because the green light-emitting element has large delay characteristics during falling and rising in comparison with the red light-emitting element and the blue light-emitting element, light is inadvertently emitted. The light emission of the green light-emitting element may affect the operation of the electronic optical device disposed in the display area of the display panel.

Next, capacitance properties of the capacitors in accordance with the drive voltages of the light-emitting elements of the red, green, and blue subpixels SPR, SPG, and SPB are compared with reference to FIG. 10B. It can be seen that the blue light-emitting element and the green light-emitting element have high capacitance properties at a drive voltage of 2 V to 2.5 V, and the red light-emitting element has relatively low capacitance properties.

The luminance properties in accordance with the drive voltages of the light-emitting elements of the red, green, and blue subpixels SPR, SPG, and SPB are compared with reference to FIG. 10C. It can be seen that the light of the green light-emitting element has higher luminous efficiency than the red light-emitting element and the blue light-emitting element at a low voltage of 2 V to 2.5 V.

That is, in comparison with the red light-emitting element and the blue light-emitting element, the green light-emitting element has high capacitance and high luminance properties during the same voltage operation. Furthermore, the green light-emitting element has rising and falling delay properties when the green light-emitting element is turned on/off, which may cause inadvertent light emission by residual charges during the operation with a low gradation. The inadvertent light emission of the green light-emitting element affects the operation of the electronic optical device disposed in the display area of the display panel, which may cause an operation defect.

In order to suppress the above-mentioned problem, in the organic light-emitting display device 100 according to the embodiment of the present specification, the third auxiliary hole transport layer is additionally provided on the second auxiliary hole transport layer of the light-emitting element of the green subpixel SPG, and the position of the top surface of the anode is lowered, which may increase the optical distance of the light-emitting element of the green subpixel. Therefore, the capacitance of the green subpixel may be decreased, and the light-emitting luminance may be quickly decreased when the green subpixel is turned off, such that the falling delay time may be reduced, and the delayed light emission of the green light-emitting element may be reduced.

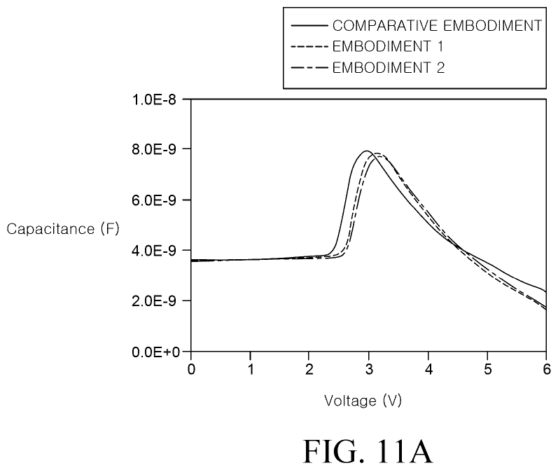

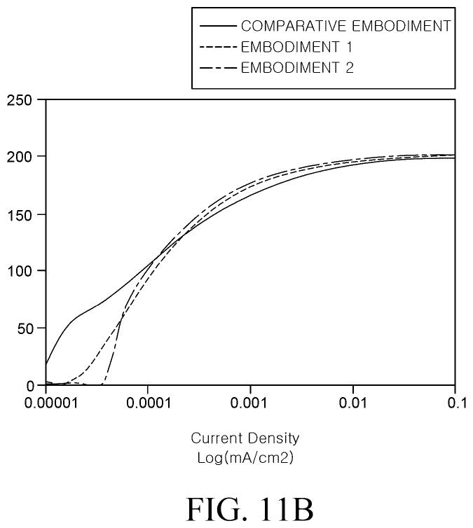

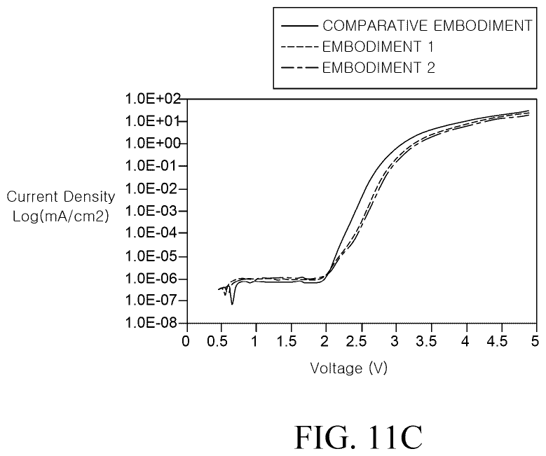

Hereinafter, an effect achieved by the configuration of the organic light-emitting display device 100 according to the embodiment of the present specification will be described more specifically with reference to FIGS. 11A to 11B.

FIGS. 11A to 11C are graphs illustrating electrical properties of the green subpixels SPG according to Comparative Embodiment 1 and Embodiments 1 and 2. FIG. 11A is a graph illustrating capacitance in accordance with the drive voltages of the green subpixels SPG according to Comparative Embodiment 1 and Embodiments 1 and 2. FIG. 11B is a graph illustrating luminance properties in accordance with the drive voltages of the green subpixels SPG according to Comparative Embodiment 1 and Embodiments 1 and 2. FIG. 11C is a graph illustrating electric current density properties in accordance with the drive voltages of the green subpixels SPG according to Comparative Embodiment 1 and Embodiments 1 and 2.

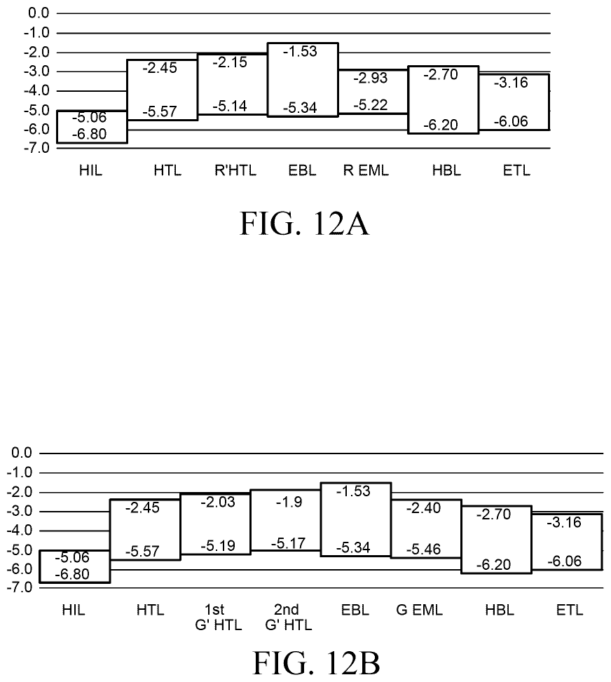

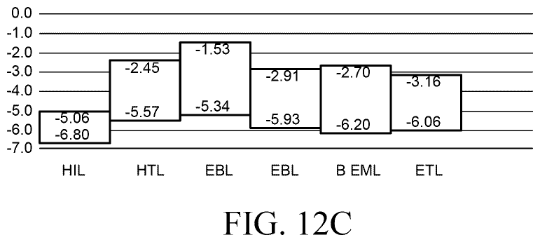

In Embodiment 1, in the organic light-emitting display device 100 illustrated in FIG. 8, the second auxiliary hole transport layer 1st G′HTL (HOMO energy level: −5.19, LUMO energy level: −2.03, hole mobility: 5.99×10⁻⁵ cm²/Vs) of the green subpixel SPG has a thickness of 330 μm, and the third auxiliary hole transport layer 2nd G′HTL (HOMO energy level: −5.17, LUMO energy level: −1.9, hole mobility: 2.11×10⁻⁷ cm²/Vs) has a thickness of 30 μm. Embodiment 2 was manufactured in substantially the same way as Embodiment 1, except that the thickness of the third auxiliary hole transport layer 2nd G′HTL was changed to 50 μm. FIGS. 12A to 12C illustrate the HOMO energy levels and the LUMO energy levels of the hole injection layer, the hole transport layer, the auxiliary hole transport layer, the electron blocking layer, the organic light-emitting layer, the hole blocking layer, and the electron transport layer of the light-emitting element of each of the red, green, and blue subpixels SPR, SPG, and SPB in the organic light-emitting display devices 100 according to Embodiments 1 and 2.

First, with reference to FIG. 11A, it can be seen that the maximum capacitance of Embodiments 1 and 2 is reduced, and a rate at which the capacitance is decreased is high in comparison with Comparative Embodiment 1. On the basis of the formula related to the capacitance (C=ε, C: capacitance, ε: dielectric constant, S: electrode area, d: distance between electrodes), the optical distance of the green subpixel SPG is further increased in Embodiments 1 and 2 than Comparative Embodiment 1, such that the capacitance may be decreased, and the luminance of the green light-emitting element may be quickly decreased when the green light-emitting element is turned off, which may reduce the falling delay time. As described with reference to FIG. 10A, the green light-emitting element generally has a larger falling delay than the red and blue light-emitting elements. Therefore, the decrease in falling delay time in Embodiments 1 and 2 may suppress a problem in which inadvertent green light affects the electronic optical device positioned below the display panel through the transmissive area by the falling delay when the green light-emitting element is turned off.

In addition, with reference to FIG. 11B, it can be seen that the luminous efficiency is decreased during the operation with a low gradation in Embodiments 1 and 2 in comparison with Comparative Embodiment 1. That is, during the operation with a low gradation, the luminance of the green subpixel SPG is higher than the luminance of the red and blue subpixels SPB, which may suppress the problem in which the inadvertent green light affects the electronic optical device positioned below the display panel through the transmissive area.

With reference to FIG. 11C, it can be seen that the threshold voltage is further increased in Embodiments 1 and 2 than Comparative Embodiment 1. Therefore, the green subpixel SPG emits light before the red and blue subpixels SPB when the green subpixel SPG is turned on, which may suppress the problem in which the inadvertent green light affects the electronic optical device positioned below the display panel through the transmissive area.

Meanwhile, as shown in Table 1, the threshold voltages and the luminous efficiency of Embodiment 2 and Comparative Embodiment 2 are evaluated based on Comparative Embodiment 1. In comparison with Embodiment 2, in Comparative Embodiment 2, only the third auxiliary hole transport layer 2nd G′HTL (HOMO energy level: −5.17, LUMO energy level: −1.9) is formed to have a thickness of 380 μm instead of the structure in which the second auxiliary hole transport layer 1st G′HTL (330 μm) and the third auxiliary hole transport layer 2nd G′HTL (50 μm) are formed in the green subpixel SPG.

TABLE 1

| | SPG auxiliary hole | | Luminous |
|---|---|---|---|
| | transport layer | ΔVth | efficiency (%) |
| Comparative | 1^{st} G′ HTL(330) | 0.0 | 100 |
| Embodiment 1 | | | |
| Comparative | 2^{nd} G′ HTL(380) | +0.14 | 99 |
| Embodiment 2 | | | |
| Embodiment 1 | 1^{st} G′ HTL(330) + | +0.2 | 101 |
| | 2^{nd} G′ HTL(50) | | |

With reference to Table 1, it can be seen that in Embodiment 1 in which the third auxiliary hole transport layer 2nd G′HTL having low mobility and a small refractive index is added below the second auxiliary hole transport layer 1st G′HTL, both the threshold voltage and the luminous efficiency are increased in comparison with Comparative Embodiment 1 including only the second auxiliary hole transport layer 1st G′HTL. Meanwhile, it can be seen that in Comparative Embodiment 2 in which the third auxiliary hole transport layer 2nd G′HTL added to Embodiment 1 is formed to have only a thickness of 380 μm without the second auxiliary hole transport layer 1st G′HTL, the threshold voltage is increased by the increase in the optical distance, but the luminous efficiency is rather decreased in comparison with Comparative Embodiment 1.

The exemplary embodiments of the present disclosure can also be described as follows:

According to an aspect of the present disclosure, there is provided an organic light-emitting display device. The organic light-emitting display device includes a substrate on which red, green, and blue subpixels are disposed, the substrate comprising a first display area comprising a light-emitting area and a transmissive area, and a second display area configured to surround the first display area; anodes separated and respectively disposed in the red, green, and blue subpixels; hole transport layers disposed on the anodes; red, green, and blue organic light-emitting layers respectively disposed in the red, green, and blue subpixels on the hole transport layer; a second auxiliary hole transport layer disposed between the green organic light-emitting layer and the hole transport layer of the green subpixel; a third auxiliary hole transport layer disposed on the second auxiliary hole transport layer of the green subpixel and having lower hole mobility than the second auxiliary hole transport layer; electron transport layers disposed on the red, green, and blue organic light-emitting layers; and a cathode disposed on the electron transport layer. A top surface of the anode of the green subpixel is positioned to be lower than a top surface of the anode of the red subpixel and a top surface of the anode of the blue subpixel.

A thickness of the anode of the green subpixel may be smaller than a thickness of the anode of the red subpixel and a thickness of the anode of the blue subpixel.

The organic light-emitting display device may further comprise planarization layers disposed between the substrate and the anodes. A thickness of the planarization layer of the green subpixel is smaller than a thickness of the planarization layer of the red subpixel and a thickness of the planarization layer of the blue subpixel.

A height difference between a top surface of the anode of the green subpixel and top surfaces of the anode of the red subpixel and the anode of the blue subpixel may be 0.8 μm to 1.2 μm.

A HOMO energy level of the second auxiliary hole transport layer may be −5.16 to −5.22, a LUMO energy level of the second auxiliary hole transport layer may be −2.00 to −2.06, a HOMO energy level of the third auxiliary hole transport layer is −5.14 to −5.20, and a LUMO energy level of the third auxiliary hole transport layer may be −1.87 to −1.93.

The third auxiliary hole transport layer may have a smaller refractive index value than the second auxiliary hole transport layer.

The refractive index value of the third auxiliary hole transport layer may be smaller by 0.05 to 0.2 than the refractive index value of the second auxiliary hole transport layer.

Hole mobility of the second auxiliary hole transport layer may be 10⁻⁴ to 5×10⁻⁶ [cm²/Vs], and hole mobility of the third auxiliary hole transport layer is 5×10⁻⁶ to 10⁻⁸ [cm²/Vs].

The organic light-emitting display device may further comprise a first auxiliary hole transport layer disposed between the red organic light-emitting layer and the hole transport layer of the red subpixel. A thickness of the first auxiliary hole transport layer may be larger than a thickness of the second auxiliary hole transport layer.

The organic light-emitting display device may further comprise electron blocking layers disposed below the red, green, and blue organic light-emitting layers. A HOMO energy level of the electron blocking layer may be −5.24 to −5.45, and a LUMO energy level of the electron blocking layer may be −1.43 to −1.63.

The organic light-emitting display device may further comprise an electronic optical device disposed below the substrate and configured to overlap with the first display area.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An organic light-emitting display device comprising:
a substrate on which red, green, and blue subpixels are disposed, the substrate comprising a first display area comprising a light-emitting area and a transmissive area, and a second display area configured to surround the first display area;
anodes separated and respectively disposed in the red, green, and blue subpixels;
hole transport layers disposed on the anodes;
red, green, and blue organic light-emitting layers respectively disposed in the red, green, and blue subpixels on the hole transport layer;
a second auxiliary hole transport layer disposed between the green organic light-emitting layer and the hole transport layer of the green subpixel;
a third auxiliary hole transport layer disposed on the second auxiliary hole transport layer of the green subpixel and having lower hole mobility than the second auxiliary hole transport layer;
electron transport layers disposed on the red, green, and blue organic light-emitting layers; and
a cathode disposed on the electron transport layer,
wherein a top surface of the anode of the green subpixel is positioned to be lower than a top surface of the anode of the red subpixel and a top surface of the anode of the blue subpixel.

2. The organic light-emitting display device of claim 1, wherein a thickness of the anode of the green subpixel is smaller than a thickness of the anode of the red subpixel and a thickness of the anode of the blue subpixel.

3. The organic light-emitting display device of claim 1, further comprising:
planarization layers disposed between the substrate and the anodes,
wherein a thickness of the planarization layer of the green subpixel is smaller than a thickness of the planarization layer of the red subpixel and a thickness of the planarization layer of the blue subpixel.

4. The organic light-emitting display device of claim 1, wherein a height difference between a top surface of the anode of the green subpixel and top surfaces of the anode of the red subpixel and the anode of the blue subpixel is 0.8 μm to 1.2 μm.

5. The organic light-emitting display device of claim 1, wherein a HOMO energy level of the second auxiliary hole transport layer is −5.16 to −5.22, a LUMO energy level of the second auxiliary hole transport layer is −2.00 to −2.06, a HOMO energy level of the third auxiliary hole transport layer is −5.14 to −5.20, and a LUMO energy level of the third auxiliary hole transport layer is −1.87 to −1.93.

6. The organic light-emitting display device of claim 1, wherein the third auxiliary hole transport layer has a smaller refractive index value than the second auxiliary hole transport layer.

7. The organic light-emitting display device of claim 6, wherein the refractive index value of the third auxiliary hole transport layer is smaller by 0.05 to 0.2 than the refractive index value of the second auxiliary hole transport layer.

8. The organic light-emitting display device of claim 1, wherein hole mobility of the second auxiliary hole transport layer is 10⁻⁴ to 5×10⁻⁶ [cm²/Vs], and hole mobility of the third auxiliary hole transport layer is 5×10⁻⁶ to 10⁻⁸ [cm²/Vs].

9. The organic light-emitting display device of claim 1, further comprising:
a first auxiliary hole transport layer disposed between the red organic light-emitting layer and the hole transport layer of the red subpixel,
wherein a thickness of the first auxiliary hole transport layer is larger than a thickness of the second auxiliary hole transport layer.

10. The organic light-emitting display device of claim 1, further comprising:
electron blocking layers disposed below the red, green, and blue organic light-emitting layers,
wherein a HOMO energy level of the electron blocking layer is −5.24 to −5.45, and a LUMO energy level of the electron blocking layer is −1.43 to −1.63.

11. The organic light-emitting display device of claim 1, further comprising:
an electronic optical device disposed below the substrate and configured to overlap with the first display area.
